(19) United States
(12) Patent Application Publication
(10) Pub. No.: US 2026/0113934 A1
(43) Pub. Date: Apr. 23, 2026

(54) READ-ONLY MEMORY AND METHOD OF FABRICATING THE SAME

(71) Applicant: TAIWAN SEMICONDUCTOR MANUFACTURING COMPANY, LTD., Hsinchu (TW)

(72) Inventors: Ya-Hui WU, Hsinchu (TW); Ling-Fang HSU, Hsinchu (TW); Tzu-Yu CHEN, Hsinchu (TW); Che-Wei CHANG, Hsinchu (TW); Chia-En HUANG, Hsinchu (TW); Ting-Wei CHIANG, Hsinchu (TW)

(21) Appl. No.: 18/922,903

(22) Filed: Oct. 22, 2024

(51) Int. Cl. H10B 20/00

(52) U.S. Cl. CPC H10B 20/387

(57) ABSTRACT

A semiconductor device includes a substrate including an active area and a well region, a bitcell including a first gate structure and a second gate structure extending in a first direction across the active area and spaced apart in a second direction; a first conductive structure at a first side of the first gate structure; a second conductive structure between a second side of the first gate structure and a first side of the second gate structure; and a third conductive structure at a second side of the second gate structure; a fourth conductive structure vertically overlapping the well region; a first conductor connected to the first conductive structure and the third conductive structure; a second conductor connected to the fourth conductive structure; and a third conductor connected to the first and second gate structures. The second and fourth conductive structures are electrically connected to the well region.

### BACKGROUND

Some semiconductor devices include read-only memory (ROM) structures to store information. One type of ROM is programmed or encoded during fabrication of the semiconductor device to provide fixed information, which does not change during device operation or in the absence of power. Such a ROM can be referred to as being configured in hardware.

ROM device density and device performance depends at least in part on routing, e.g., routing of bitline conductors, wordline conductors, reference voltage conductors, and the like. Congestion in routing can result in less than optimal conductor dimensions leading to increased resistance, and can limit increases in bitcell density.

### BRIEF DESCRIPTION OF THE DRAWINGS

FIG. 1A is a schematic plan view of a semiconductor device according to at least one embodiment, FIG. 1B is a cross-sectional view corresponding to a line A-A′ in FIG. 1A, and FIG. 1C is a cross-sectional view corresponding to a line B-B′ in FIG. 1A.

FIG. 2A is a schematic plan view of a semiconductor device according to at least one embodiment, FIG. 2B is a cross-sectional view corresponding to a line A-A′ in FIG. 2A, and FIG. 2C is a cross-sectional view corresponding to a line B-B′ in FIG. 2A.

FIG. 3A is a schematic plan view of a semiconductor device according to at least one embodiment, FIG. 3B is a cross-sectional view corresponding to a line A-A′ in FIG. 3A, and FIG. 3C is a cross-sectional view corresponding to a line B-B′ in FIG. 3A.

FIG. 4A is a schematic plan view of a semiconductor device according to at least one embodiment, FIG. 4B is a cross-sectional view corresponding to a line A-A′ in FIG. 4A, and FIG. 4C is a cross-sectional view corresponding to a line B-B′ in FIG. 4A.

FIG. 5A is a schematic plan view of a semiconductor device according to at least one embodiment, FIG. 5B is a cross-sectional view corresponding to a line A-A′ in FIG. 5A, and FIG. 5C is a cross-sectional view corresponding to a line B-B′ in FIG. 5A.

FIG. 6A is a schematic plan view of a semiconductor device according to at least one embodiment, FIG. 6B is a cross-sectional view corresponding to a line A-A′ in FIG. 6A, and FIG. 6C is a cross-sectional view corresponding to a line B-B′ in FIG. 6A.

FIG. 7A is a schematic plan view of a semiconductor device according to at least one embodiment, FIG. 7B is a cross-sectional view corresponding to a line A-A′ in FIG. 7A, and FIG. 7C is a cross-sectional view corresponding to a line B-B′ in FIG. 7A.

FIG. 8A is a schematic plan view of a semiconductor device according to at least one embodiment, FIG. 8B is a cross-sectional view corresponding to a line A-A′ in FIG. 8A, and FIG. 8C is a cross-sectional view corresponding to a line B-B′ in FIG. 8A.

FIG. 9A is a schematic plan view of a semiconductor device according to at least one embodiment, FIG. 9B is a cross-sectional view corresponding to a line A-A′ in FIG. 9A, and FIG. 9C is a cross-sectional view corresponding to a line B-B′ in FIG. 9A.

FIG. 10A is a schematic plan view of a semiconductor device according to at least one embodiment, FIG. 10B is a cross-sectional view corresponding to a line A-A′ in FIG. 10A, and FIG. 10C is a cross-sectional view corresponding to a line B-B′ in FIG. 10A.

FIG. 11A is a schematic plan view of a semiconductor device according to at least one embodiment, FIG. 11B is a cross-sectional view corresponding to a line A-A′ in FIG. 11A, and FIG. 11C is a cross-sectional view corresponding to a line B-B′ in FIG. 11A.

FIG. 12A is a schematic plan view of a semiconductor device according to at least one embodiment, FIG. 12B is a cross-sectional view corresponding to a line A-A′ in FIG. 12A, and FIG. 12C is a cross-sectional view corresponding to a line B-B′ in FIG. 12A.

FIG. 13A is a schematic plan view of a semiconductor device according to at least one embodiment, FIG. 13B is a cross-sectional view corresponding to a line A-A′ in FIG. 13A, and FIG. 13C is a cross-sectional view corresponding to a line B-B′ in FIG. 13A.

FIG. 14A is a schematic plan view of a semiconductor device according to at least one embodiment, FIG. 14B is a cross-sectional view corresponding to a line A-A′ in FIG. 14A, FIG. 14C is a cross-sectional view corresponding to a line B-B′ in FIG. 14A, and FIG. 14D is a cross-sectional view corresponding to a line C-C′ in FIG. 14A.

FIG. 15 is a flowchart of a method of fabricating a semiconductor device according to at least one embodiment.

FIG. 16 is a block diagram of an IC device, according to at least one embodiment.

FIG. 17 is a block diagram of an electronic design automation (EDA) system in accordance with some embodiments.

FIG. 18 is a block diagram of an integrated circuit (IC) manufacturing system, and an IC manufacturing flow associated therewith, according to at least one embodiment.

### DETAILED DESCRIPTION

The following disclosure provides many different embodiments, or examples, for implementing different features of the provided subject matter. Specific examples of components, values, steps, operations, materials, arrangements, or the like, are described below to simplify the present disclosure. These are, of course, merely examples and are not intended to be limiting. Other components, values, operations, materials, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A ROM semiconductor device according to at least one embodiment is configured in hardware and includes conductive structures, e.g., a well region or a backside conductor, that provide one or more of bitline, wordline, and/or reference signals and/or voltages. The use of one or more of a well region or a backside conductor provides greater routing flexibility than using a single metal layer for routing. Thus, whereas another approach provides all of bitline, wordline, and/or reference signals and/or voltages in a single metal layer, e.g., an M0 layer, embodiments provide more routing options by providing for bitline, wordline, and/or reference signals and/or voltages to be routed in one or more of a frontside metal layer such as an M0 layer, a well region, and/or a backside metal layer such as a BM0 layer.

In some embodiments, ROM density, i.e., ROM data capacity per unit area, is increased by providing additional routing flexibility and reducing a number of conductors in a given metal layer. In some embodiments, a cell height is reduced by reducing a number of conductors in the given metal layer. In some embodiments, two conductors in an M0 layer overlie a ROM cell, and cell height (in an X-axis direction) is reduced by using one or more of a well region or a backside conductor in place of an M0 conductor. In some embodiments, a cell height is about 100 nm or less.

In some embodiments, a ROM semiconductor device is provided with electrical pathways, e.g., through a well region, using pre-existing process operations, e.g., by modification of an existing mask, to provide increased bitcell density without significant additional process costs.

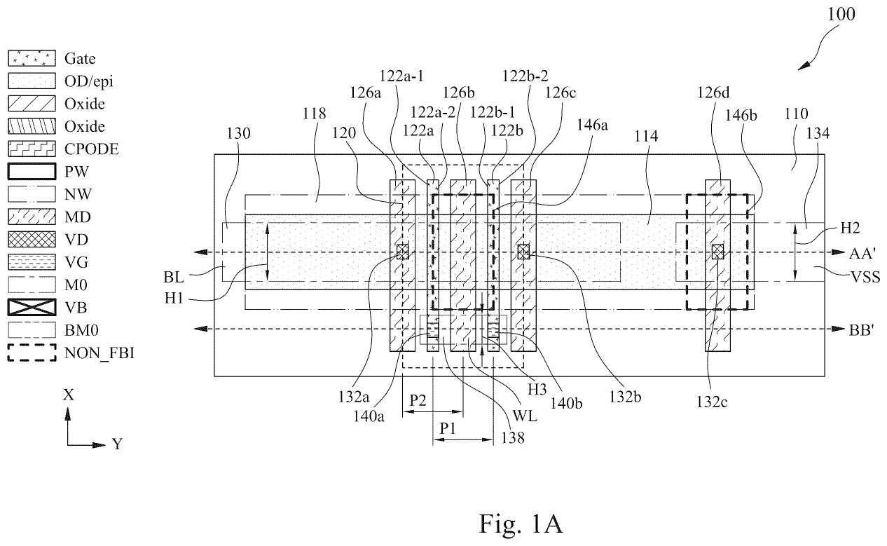

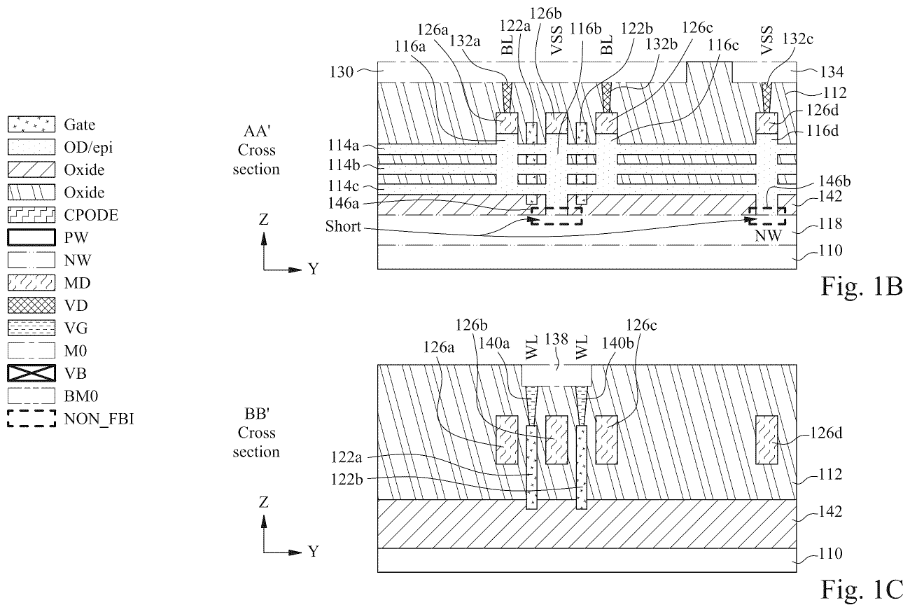

FIG. 1A is a schematic plan view of a semiconductor device 100 according to at least one embodiment, FIG. 1B is a cross-sectional view corresponding to a line A-A′ in FIG. 1A, and FIG. 1C is a cross-sectional view corresponding to a line B-B′ in FIG. 1A.

Referring to FIG. 1A, the semiconductor device 100 includes a substrate 110 including an active area 114 and a well region 118 under the active area 114.

In some embodiments, the substrate 110 includes an elemental semiconductor including silicon, germanium, or the like in a crystal, polycrystalline, or amorphous structure, a compound semiconductor including silicon carbide, gallium arsenic, gallium phosphide, indium phosphide, indium arsenide, indium antimonide or the like, an alloy semiconductor including SiGe, GaAsP, AlInAs, AlGaAs, GaInAs, GaInP, GaInAsP, or the like, or a combination thereof. In some embodiments, the substrate 100 has a gradient SiGe characteristic in which the Si and Ge composition change from one ratio at one location to another ratio at another location in the substrate. In some embodiments, an alloy of SiGe is formed over a silicon layer. In some embodiments, the substrate 110 is a strained SiGe substrate. In some embodiments, the substrate 110 has a semiconductor-on-insulator structure, e.g., a silicon-on-insulator (SOI) structure. In some embodiments, the substrate 110 includes a doped epitaxial (epi) layer and/or a buried layer. In some embodiments, the substrate 110 has a multilayer structure or includes a multilayer compound semiconductor structure.

In some embodiments, the well region 118 is an N-well region, i.e., a region doped with one or more N-type dopants. In some embodiments, the well region is a P-well region, i.e., a region doped with one or more P-type dopants. In some embodiments, the well region 118 is silicon, silicon-germanium, or the like.

In FIG. 1A, a bitcell region 120 encoding one bit having a first logic value, e.g., a logic ‘1’, vertically overlaps the well region 118. The bitcell region 120 includes a first gate structure 122a that extends in a first direction (parallel to the X axis) across the active area 114, and includes a second gate structure 122b that extends in the first direction across the active area 114 and is spaced apart in a second direction (parallel to the Y axis) from the first gate structure 122a. The first gate structure 122a and the second gate structure 122b are arranged at a first pitch P1 along the second direction. In some embodiments, the first pitch P1 is determined based on a center-to-center distance of immediately-adjacent gate structures (i.e., having no intervening gate structures) in the second direction. A first conductive structure 126a is at a first side 122a-1 of the first gate structure 122a, a second conductive structure 126b is between a second side 122a-2 of the first gate structure 122a and a first side 122b-1 of the second gate structure 122b, and a third conductive structure 126c is at a second side 122b-2 of the second gate structure 122b. The first, second, and third conductive structures 126a˜126c extend in the first direction. The first conductive structure 126a and the second conductive structure 126b are arranged at a second pitch P2 along the second direction. In some embodiments, the second pitch P2 is determined based on a center-to-center distance of immediately-adjacent conductive structures (i.e., having no intervening conductive structures) in the second direction. The second conductive structure 126b and the third conductive structure 126c are also arranged at the second pitch P2 along the second direction.

The first and second gate structures 122a, 122b are configured to receive a signal, e.g., a wordline signal, to control conductivity of corresponding channel regions of the active area 114. In FIGS. 1A˜1C, the bitcell region 120 is shown as including two gate structures, i.e., the first and second gate structures 122a, 122b. In some embodiments, a single gate structure is provided. In still other embodiments, more than two gate structures are provided. Increasing the number of gate structures increases driving current although increasing the number of gate structures also increases cell width.

In some embodiments, the first and second gate structures 122a, 122b include polysilicon or a metal. In some embodiments, the first and second gate structures 122a, 122b include multiple layers, e.g., a gate dielectric layer crossing or wrapping the active area 114, a gate electrode including a work function metal layer formed over the gate dielectric layer, a bulk conductive layer formed over the work function metal layer, and the like. In some embodiments, the gate dielectric layer includes a high-k layer of one or more high-k dielectric materials (or one or more layers of high-k dielectric materials), e.g., one or more of aluminum oxide, hafnium oxide, hafnium silicon oxide, lanthanum oxide, strontium titanate, titanium oxide, yttrium oxide, zirconium oxide, or the like. In some embodiments, the work function metal layer includes one or more of aluminum, molybdenum, platinum, ruthenium, tantalum carbide, tantalum carbide nitride, tantalum nitride, tantalum silicon nitride, titanium, titanium nitride, titanium silicon nitride, tungsten, or the like. In some embodiments, the work function metal layer includes multiple material layers of the same or different types (e.g., both n-type work function metal or both p-type work function metal) in order to achieve a desired threshold voltage. In some embodiments, the bulk conductive layer includes one or more of aluminum, cobalt, copper, ruthenium, tungsten, or the like. In some embodiments, the first and second gate structures 122a, 122b include other material layers, e.g., one or more of a barrier layer, a glue layer, a hard mask layer, a capping layer, or the like. In some embodiments, various layers of the first and second gate structures 122a, 122b are formed by atomic layer deposition, chemical or thermal oxidation, chemical vapor deposition, physical vapor deposition, plating, or the like.

The first, second, and third conductive structures 126a, 126b, 126c include a conductive material, e.g., one or more metals such as copper, silver, aluminum, tungsten, titanium, nickel, tin, cobalt, or the like, or another conductive material such as doped semiconductor or epitaxial material doped at a level sufficient to provide low resistivity, such as one or more of arsenic, boron, gallium, phosphorus, silicon, silicon carbide, silicon germanium, or the like. The first, second, and third conductive structures 126a, 126b, 126c may be referred to as MD patterns, MD segments, MD structures, or the like.

A fourth conductive structure 126d that vertically overlaps the well region 118 is spaced apart from the third conductive structure 126c in the second direction. In some embodiments, the fourth conductive structure 126d is located at a position that is n×second pitch P2 in the second direction from the third conductive structure 126c, where n is an integer of 1 or more. In some embodiments, the fourth conductive structure 126d is formed of a same material used to form the first, second, and third conductive structures 126a, 126b, 126c. In some embodiments, one or more of the first, second, third, and fourth conductive structures 126a, 126b, 126c, 126d is formed of a material different from one or more others of the first, second, third, and fourth conductive structures 126a, 126b, 126c, 126d.

A first conductor 130 is electrically connected to the first conductive structure 126a and the third conductive structure 126c. The first conductor 130 extends in the second direction and vertically overlaps the active area 114. The first conductor 130 is electrically connected to the first conductive structure 126a by a first via 132a. The first conductor 130 is electrically connected to the third conductive structure 126c by a second via 132b. In FIGS. 1A˜1C, the first conductor 130 is configured as a bitline (BL) of the bitcell region 120. In some embodiments, the first conductor 130 is configured to provide a reference voltage, e.g., VSS.

A second conductor 134 is electrically connected to the fourth conductive structure 126d by a third via 132c. The second conductor 134 extends in the second direction and vertically overlaps the active area 114. The second conductor 134 is configured to provide a reference voltage, e.g., a constant voltage. In FIGS. 1A˜1C, the second conductor is configured to provide VSS. In some embodiments, the second conductor 134 is configured to provide a reference voltage other than VSS. In some embodiments, the second conductor 134 is configured as a bitline.

A third conductor 138 extends in the second direction, and is electrically connected to the first gate structure 122a and the second gate structure 122b. Referring to FIG. 1C, the third conductor 138 is electrically connected to the first gate structure 122a by a first gate via 140a. The third conductor 138 is electrically connected to the second gate structure 122b by a second gate via 140b. In FIGS. 1A˜IC, the third conductor 138 is configured as a wordline (WL).

The first, second, and third conductors 130, 134, 138 include one or more conductive materials, e.g., one or metals such as aluminum, copper, nickel, silver, tin, titanium, tungsten, or the like. In some embodiments, each of the first, second, and third conductors 130, 134, 138 is formed of a same material in a same layer, e.g., a same metal layer, e.g., M0. In some embodiments, one or more of the first, second, and third conductors 130, 134, 138 are formed from a different material from one or more other ones of the first, second, and third conductors 130, 134, 138.

The first, second, and third vias 132˜132c include one or more conductive materials, e.g., one or more metals such as aluminum, copper, tantalum, titanium, tungsten, or the like. In some embodiments, each of the first, second, and third vias 132˜132c is formed of a same material in a same layer, e.g., VD. In some embodiments, one or more of the first, second, and third vias 132˜132c are formed from a different material from one or more other ones of the first, second, and third vias 132˜132c.

The first and second gate vias 140a, 140b include one or more conductive materials, e.g., one or more metals such as aluminum, copper, tantalum, titanium, tungsten, or the like. In some embodiments, each of the first and second gate vias 140a, 140b is formed of a same material in a same layer, e.g., VG. In some embodiments, one of the first and second gate vias 140a, 140b is formed from a different material from the other of the first and second gate vias 140a, 140b.

In the semiconductor device 100, a height H1 of the first conductor 130, as determined in the first direction, is substantially the same as a height H2 of the second conductor 134, as determined in the first direction, and the first conductor 130 and the second conductor 134 are substantially centered along a same virtual line, or track, extending in the second direction. The heights H1 and H2 are greater than a height H3 of the third conductor 138 in the second direction. Increasing the height H1 and/or the height H2 helps to reduce resistance on the first conductor 130 and/or the second conductor 134, while reducing the height H3 helps to maintain clearance in the first direction between the first conductor 130 and the third conductor 138 and helps to reduce cell height. In at least one embodiment such as the embodiment of FIGS. 1A˜IC in which the first conductor 130 is configured as a bitline, increasing the height H1 helps to reduce resistance of the bitline.

Referring again to FIG. 1A, the third conductor 138 is spaced apart in the first direction from the well region 118, i.e., the third conductor 138 and the first and second gate vias 140a, 140b do not vertically overlap the well region 118. In some embodiments, the third conductor 138 wholly or partially vertically overlaps the well region 118 and/or the first and second gate vias 140a, 140b wholly or partially vertically overlap the well region 118. In some embodiments, the third conductor 138 and/or the first and second gate vias 140a, 140b wholly or partially vertically overlap the well region 118 while being spaced apart in the first direction from the active area 114. In some embodiments, the third conductor 138 and/or the first and second gate vias 140a, 140b wholly or partially vertically overlap the active area 114.

In FIG. 1A, the first, second, third, and fourth conductive structures 126a˜126d are in an MD layer, and the first, second, and third conductors 130, 134, 138 are in an M0 layer. M0 refers to the first metal layer in a sequence of metal layers, e.g., M0, M1, M2, M3, M4, M5, and the like, with M0 being the first metal layer over the MD layer, and where the MD layer is a conductive layer (also referred to as a metal-over-diffusion layer) forming source/drain contacts directly on the active area 114 (which is sometimes referred to as a oxide-defined or OD region) and generally at a same level as a poly layer or gate layer. In some embodiments, the metal layers, e.g., one or more of M0, M1, M2, M3, M4, M5, and the like, are formed of one or more of aluminum, copper, tantalum, titanium, tungsten, or the like. In some embodiments, one or more of the first, second, and third conductors 130, 134, 138 are in a layer other than the M0 layer, e.g., a layer such as M1, M2, or the like over the M0 layer. In still other embodiments, one or more of the first, second, and third conductors 130, 134, 138 are in a backside metal layer, e.g., BM0, as described below.

Referring to FIG. 1B, the active area 114 includes a plurality of nanostructures, i.e., first, second, and third nanostructures 114a, 114b, 114c, which are surrounded at least in part by a dielectric material 112. In some embodiments, the nanostructures serve as channels of one or more transistors. In some embodiments, the transistors are gate-all-around field effect transistors (GAA FETs). In some embodiments, other transistor structures are used. The first and second gate structures 122a, 122b surround channel regions of the nanostructures 114a˜114c.

In some embodiments, the nanostructures 114a˜114c include a semiconductor material, e.g., silicon or a silicon compound such as silicon germanium, or the like. In some embodiments, the nanostructures 114a˜114c have sizes that are in a range of a few nanometers, and have an elongated shape extending parallel to the Y axis. In some embodiments, the nanostructures 114a˜114c are nanowires, nanosheets, nanotubes, or the like. In some embodiments, the nanostructures 114a˜114c have cross-sectional profiles (e.g., in the X-Z plane) that are rectangular, round, square, circular, elliptical, hexagonal, or the like. In some embodiments, the nanostructures 114a˜114c include a continuous volume of one or more layers of one or more semiconductor materials having either n-type or p-type doping. In some embodiments, individual nanosheet layers include a single monolayer or multiple monolayers of a semiconductor material.

First, second, and third epitaxial structures 116a, 116b, 116c each surround the nanostructures 114a˜114c and are electrically connected to the nanostructures 114a˜114c to provide source/drain (s/d) regions adjacent to the first and second gate structures 122a, 122b. The second epitaxial structure 116b is between the first epitaxial structure 116a and the third epitaxial structure 116c relative to the second direction. The first, second, and third conductive structures 126a˜126c vertically overlap and are electrically connected to corresponding ones of the first, second, and third epitaxial structures 116a˜116c.

In some embodiments, the first, second, and third epitaxial structures 116a˜116c include a semiconductor material such as epitaxially-grown silicon germanium or boron-doped silicon, or an epitaxially-grown semiconductor such as silicon that is doped with a dopant such as one or more of carbon, phosphorous, or the like. In some embodiments, the dopant is supplied after the epitaxial growth by an implantation process. In some embodiments, the epitaxial structures are grown from a surface of the well region 118.

The second epitaxial structure 116b is electrically connected to the well region 118. A fourth epitaxial structure 116d surrounds the nanostructures 114a˜114c and is electrically connected to the nanostructures 114a˜114c and the well region 118. In some embodiments, the fourth epitaxial structure 116d is formed of a same material used to form the first, second, and third epitaxial structures 116a˜116c. In some embodiments, one or more of the first, second, third, and fourth epitaxial structures 116a˜116d are formed of a material different from one or more others of the first, second, third, and fourth epitaxial structures 116a˜116c.

The semiconductor device 100 includes an insulating structure 142 on the well region 118, between the well region 118 and the overlying active area 114. In some embodiments, the insulating structure 142 includes a plurality of insulating layers or structures, e.g., a first insulating layer directly on the well region 118 and one or more additional insulating layers on the first insulating layer, each of the first and one or more additional insulating layers being formed of a same or different insulating materials. In some embodiments, the insulating structure 142 is or includes an oxide layer. In some embodiments, the insulating structure 142 is or includes a flexible bottom isolation structure. In some embodiments, the insulating structure 142 includes a dielectric material, e.g., one or more of silicon oxide, silicon nitride, SiOCN, or the like. In some embodiments, the dielectric material is formed by a process that includes one or more of atomic layer deposition, chemical vapor deposition, physical vapor deposition, or the like.

The second epitaxial structure 116b and the fourth epitaxial structure 116d extend in a third direction (parallel to the Z axis) through openings in the insulating structure 142 and are electrically connected to the well region 118. Connecting the second epitaxial structure 116b and the fourth epitaxial structure 116d together using the well region 118 allows for a reduction in the number of conductors in a metal layer, e.g., an M0 layer, by using the well region 118 as a conductor, and thus provides design and/or layout flexibility by enabling the use of wider, lower-resistance conductors for a bitline or the like, and/or enabling a reduction in overall cell height.

In some embodiments, the second epitaxial structure 116b and the fourth epitaxial structure 116d are formed by epitaxial growth from an exposed surface of the well region 118. In some embodiments, the surface of the well region 118 is exposed by patterning the insulating structure 142 to form openings therein.

In some embodiments, the openings in the insulating structure 142 are formed using an existing lithographic operation in a fabrication process, e.g., by modifying an existing mask, rather than using an additional lithographic operation. Modifying an existing mask rather than using an additional lithographic operation helps to minimize costs.

A first area 146a in FIGS. 1A and 1B is an area where the insulating structure 142 is not present and the second epitaxial structure 116b is electrically connected to the well region 118, and a second area 146b is an area where the insulating structure 142 is not present and the fourth epitaxial structure 116d is electrically connected to the well region 118. Thus, the second epitaxial structure 116b and the fourth epitaxial structure 116d are each shorted to the well region 118. The first and second areas 146a, 146b may be referred to as non-isolation areas. In some embodiments, the selective absence or presence of the non-isolation areas in the bitcell(s) is used to encode logic values, e.g., ‘0’ and ‘1’ respectively, during device fabrication to thus provide a ROM that is encoded in hardware with fixed data in an intuitive manner.

In FIG. 1A, the first area 146a is shown as having a dimension in the first direction that extends beyond the height of active area 114 and a dimension in the second direction that extends beyond the width of the second conductive structure 126b. In some embodiments, as shown in FIG. 1B, the first area 146a is smaller in one or both of the first and second directions. In some embodiments, the first area 146a has a same area as the footprint of the second epitaxial structure 116b, i.e., the first area 146a and the second epitaxial structure 116b have a same height in the first direction and a same width in the second direction.

Similarly, in FIG. 1A, the second area 146b is shown as having a dimension in the first direction that extends beyond the height of active area 114 and a dimension in the second direction that extends beyond the width of the fourth conductive structure 126d. In some embodiments, as shown in FIG. 1B, the second area 146b is smaller in one or both of the first and second directions. In some embodiments, the second area 146b has a same area as the footprint of the second epitaxial structure 116b, i.e., the second area 146b and the second epitaxial structure 116b have a same height in the first direction and a same width in the second direction. Dimensions of the first and second areas 146a, 146b can be varied provided that the dimensions are sufficient to provide electrical connections between the second and fourth conductive structures 126b, 126d and the underlying well region 118.

The well region 118 electrically connects the second and fourth epitaxial structures 116b, 116d. A reference voltage, e.g., VSS, is supplied to the second conductor 134 and thus to the second conductive structure 126b by way of an electrical path through the well region 118. The first conductor 130 is configured as a bit line and the third conductor 138 is configured as a word line.

As described above, the second epitaxial structure 116b is electrically connected to the well region 118 and thus to the reference voltage VSS supplied to the second conductor 134. Accordingly, the bitcell region 120 encodes a first logic value, e.g., a logic ‘l’. Stated another way, the presence of the non-isolation area of the first area 146a where the second epitaxial structure 116b is on the well region 118 means that the second epitaxial structure 116b is electrically connected to the well region 118 and the bitcell region 120 encodes a first logic value, e.g., a logic ‘1’.

In some embodiments, described below, the non-isolation area is absent, i.e., the insulating structure 142 is present under the second epitaxial structure 116b such that the second epitaxial structure 116b is not electrically connected to the well region 118, and thus the bitcell encodes a second logic value, e.g., a logic ‘0’. Stated another way, the absence of the non-isolation area of the first area 146a where the second epitaxial structure 116b is on the well region 118 means that the second epitaxial structure 116b is electrically disconnected from the well region 118 and the bitcell encodes a second logic value, e.g., a logic ‘0’.

Thus, the logic value encoded by the bitcell region 120 is determined by the presence or absence of the insulating structure 142 between the second epitaxial structure 116b and the well region 118. Stated another way, the logic value encoded by the bitcell region 120 is determined by the absence or presence of the non-isolation area where the second epitaxial structure 116b is on the well region 118.

As described in further detail below, in some embodiments a ROM having a plurality of bitcells is encoded using electrical connections to and disconnections from the well region 118, with logic values of ‘1’ and ‘0’ being encoded by the absence of the non-isolation area (e.g., for ‘1’) or presence of the non-isolation area (e.g., for ‘0’).

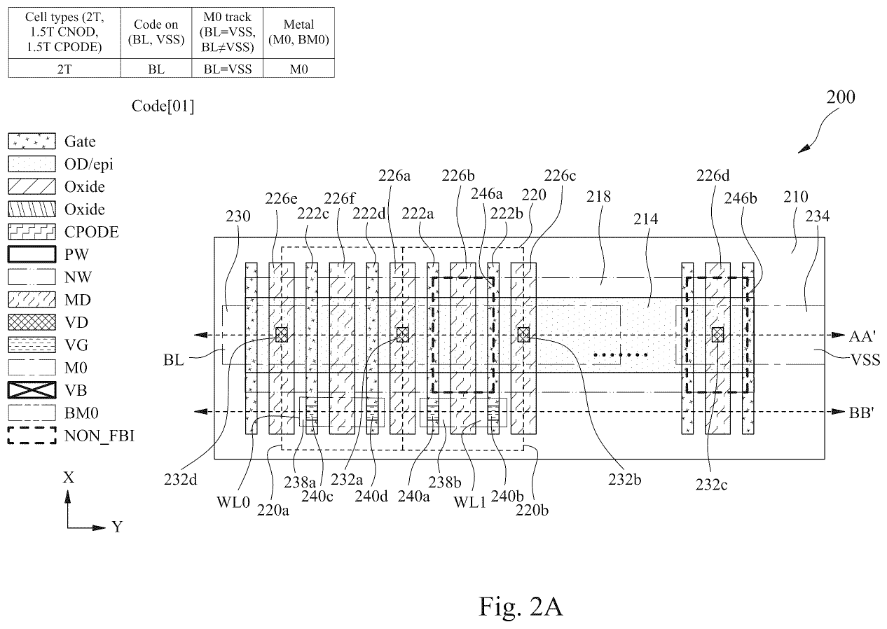

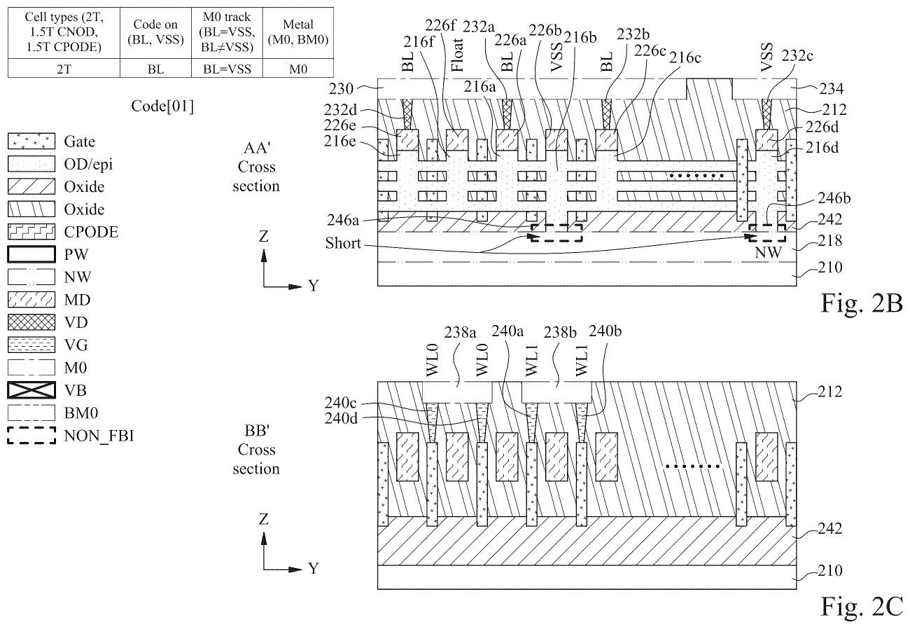

FIG. 2A is a schematic plan view of a semiconductor device 200 according to at least one embodiment, FIG. 2B is a cross-sectional view corresponding to a line A-A′ in FIG. 2A, and FIG. 2C is a cross-sectional view corresponding to a line B-B′ in FIG. 2A.

Elements of the semiconductor device 200 that are similar to elements of the semiconductor device 100 have a corresponding identifying numeral, increased by 100. Aspects of the semiconductor device 200 that are different from the semiconductor device 100 will be mainly described.

Referring to FIG. 2A, the semiconductor device 200 is an example of a 2T cell type device (2T=two transistor) in which a bitcell region 220 encodes first and second logic values that are different from each other, e.g., [01]. The first logic value, e.g., logic ‘0’, is encoded in a first bitcell 220a. The second logic value, e.g., logic ‘1’, is encoded in a second bitcell 220b corresponding to the bitcell region 120 of FIG. 1A. In the semiconductor device 200, the encodings of the first and second logic values correspond to, respectively, electrical disconnections from and electrical connections to a well region 218.

In the semiconductor device 200, a first conductor 230 extends in the second direction and vertically overlaps an active area 214, and is configured as a bitline. Also, a second conductor 234 extends in the second direction along a same virtual line, or track, as the first conductor 230 and vertically overlaps the active area 214, and is configured to provide VSS. The first conductor 230 is electrically connected to a first epitaxial structure 216a (by via 232a and conductive structure 226a), a third epitaxial structure 216c (by via 232b and conductive structure 226c), and a fifth epitaxial structure 216e (by via 232d and conductive structure 226c).

A first area 246a in FIG. 2A is an area where an insulating structure 242 (see FIGS. 2B and 2C) is not present or has an opening formed therein, and a second epitaxial structure 216b (see FIGS. 2B and 2C) is thus electrically connected to the well region 218. A second area 246b in FIG. 2A is an area where the insulating structure 242 is not present or has an opening formed therein, and a fourth epitaxial structure 216d (see FIGS. 2B and 2C) is thus electrically connected to the well region 218. Connecting the second epitaxial structure 216b and the fourth epitaxial structure 216d together using the well region 218 allows for a reduction in the number of conductors in a metal layer, e.g., an M0 layer, and thus provides layout flexibility such as enabling the use of wider, lower-resistance conductors for a bitline or the like, and/or enabling a reduction in overall cell height. The first and second areas 246a, 246b may be referred to as non-isolation areas.

The second epitaxial structure 216b is electrically connected to the well region 218 and thus to the reference voltage VSS supplied to a second conductor 234. Accordingly, in the same manner as described above for the bitcell region 120, the second bitcell 220b encodes a first logic value, e.g., logic ‘1’. Stated another way, the presence of the non-isolation area of the first area 246a where the second epitaxial structure 216b is on the well region 218 means that the second epitaxial structure 216b is electrically connected to the well region 218 and the second bitcell 220b encodes a first logic value, e.g., logic ‘1’.

On the other hand, in the first bitcell 220a, the non-isolation area is absent under a fifth epitaxial structure 216c (see FIGS. 2B and 2C), i.e., the insulating structure 242 is present under the fifth epitaxial structure 216c, such that the fifth epitaxial structure 216e is not electrically connected to the well region 218, and thus the first bitcell 220a encodes a second logic value, e.g., a logic ‘0’. Stated another way, the absence of a non-isolation area where the fifth epitaxial structure 216c is on the well region 218 means that the fifth epitaxial structure 216e is electrically disconnected from the well region 218, and thus the first bitcell 220a encodes a second logic value, e.g., a logic ‘0’. In FIGS. 2A˜2C, the sixth epitaxial structure 216f is electrically floated. In some embodiments, a voltage or signal may be applied to the sixth epitaxial structure 216f.

The logic values, e.g., [01], encoded by the bitcell region 220 are determined by the presence or absence of the insulating structure 242 isolating, respectively, the fifth epitaxial structure 216e and the second epitaxial structure 216b from the well region 218. Stated another way, the logic values encoded by the bitcell region 220 are determined by, respectively, the absence or presence of the non-isolation area where the fifth epitaxial structure 216e and the second epitaxial structure 216b are on the well region 218.

In FIGS. 2A˜2C, conductor 238a is electrically connected to gate structures 222c, 222d, and is configured as a first wordline WL0. Conductor 238b is electrically connected to gate structures 222a, 222b, and is configured as a second wordline WL1. The conductors 238a, 238b are substantially aligned along a same virtual line, or track, in the second direction.

In the semiconductor device 200, the ROM data, i.e., the data encoded in the first and second bitcells 220a, 220b of the bitcell region 220, is read by using the first and second wordlines WL0, WL1 to regulate an address input, and using the conductor 230 as a bitline to receive data output from the transistors of the bitcell region 220 of the ROM. In some embodiments, the second bitcell 220b having the non-isolation area 246b is set to correspond to a logic ‘1’ and the data read from the ROM of the semiconductor device 200 is [01]. In some embodiments, logic values are reversed, the second bitcell 220b having the non-isolation area 246b is set to correspond to a logic ‘0’, and the data read from the ROM of the semiconductor device 200 is [10]. In some embodiments, reading data from the semiconductor device 200 includes applying wordline signals to the first and second wordlines WL0, WL1 (i.e., conductors 238a, 238b), supplying VSS to the bitcell region 220 using the conductor 234 and the well region 218, reading a first logic value, e.g., a logic ‘0’, from the first bitcell 220a in which the sixth epitaxial structure 216f is not electrically connected to the well region 218, e.g., floated, and reading a second logic value, e.g., a logic ‘1’, from the second bitcell 220b in which the second epitaxial structure 216b corresponds to the non-isolation area 246a and is thus electrically connected to the well region 218 to be provided with VSS from the well region 218.

The above description of the semiconductor device 200 is an example of a two-bit ROM that encodes two different logic values, e.g., [01]. It will be understood that the semiconductor device 200 can be fabricated to connect both the second and sixth epitaxial structures 216b, 216f to the well region 218 to encode two of the same logic values, e.g., [11], or to isolate both the second and sixth epitaxial structures 216b, 216f from the well region 218 to encode two of the same logic values, e.g., [00]. In various embodiments, a greater or fewer number of transistors and/or bitcells is provided in the semiconductor device 200, and the number of bits encoded is one or more than two. In at least one embodiment, the semiconductor device 200 is implemented using a unit cell that is 2CPP. In other embodiments, a greater or lesser CPP is used.

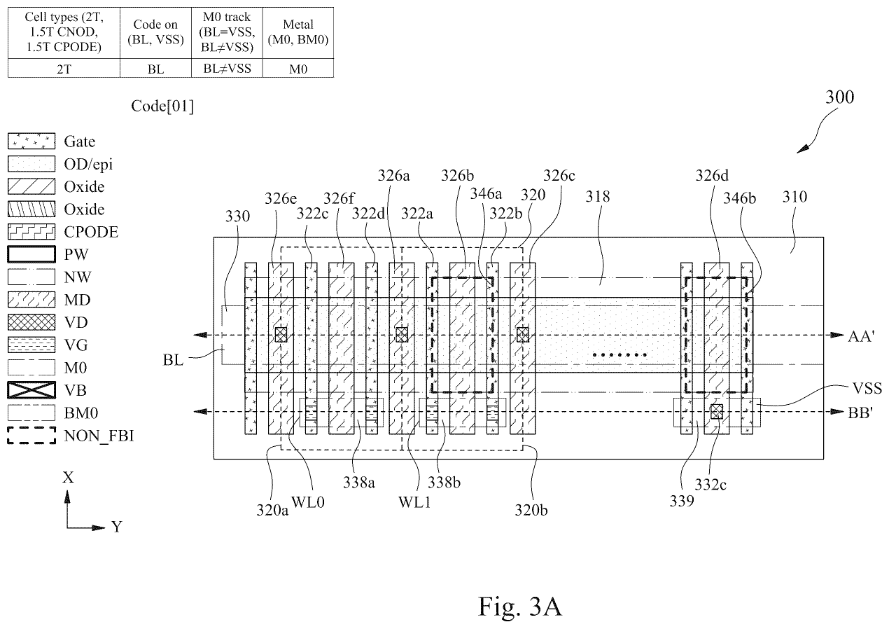

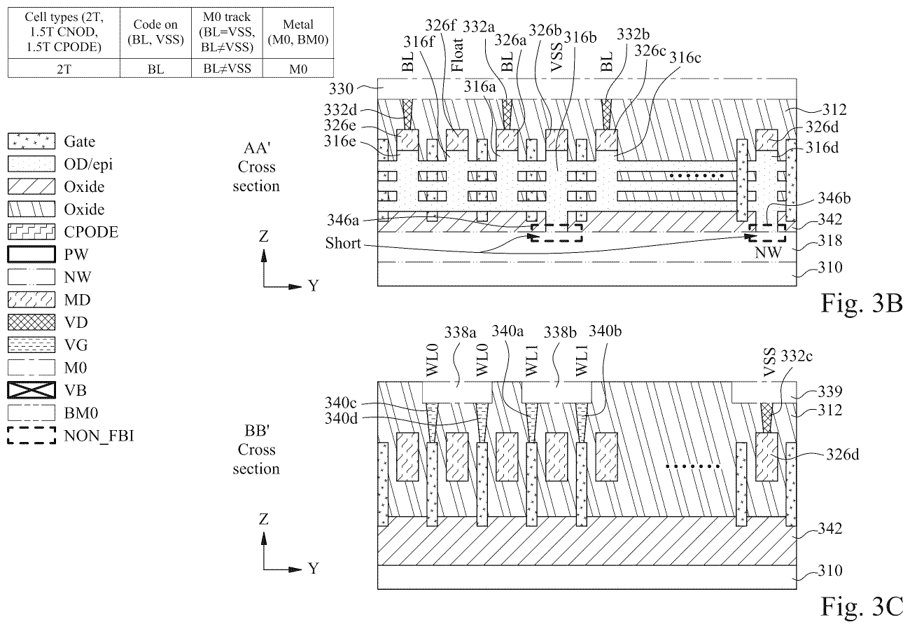

FIG. 3A is a schematic plan view of a semiconductor device 300 according to at least one embodiment, FIG. 3B is a cross-sectional view corresponding to a line A-A′ in FIG. 3A, and FIG. 3C is a cross-sectional view corresponding to a line B-B′ in FIG. 3A.

Elements of the semiconductor device 300 that are similar to elements of the semiconductor device 200 have a corresponding identifying numeral, increased by 100. Aspects of the semiconductor device 300 that are different from semiconductor device 200 will be mainly described.

Referring to FIG. 3A, the semiconductor device 300 is an example of a 2T cell type device in which a bitcell region 320 encodes first and second logic values that are different from each other, e.g., [01]. The first logic value, e.g., logic ‘0’, is encoded in a first bitcell 320a. The second logic value, e.g., logic ‘1’, is encoded in a second bitcell 320b. In the semiconductor device 300, the encodings of the first and second logic values correspond to, respectively, electrical disconnections from and electrical connections to a well region 318.

A first area 346a in FIG. 3A is an area where an insulating structure 342 (see FIGS. 3B and 3C) is not present or has an opening formed therein, and a second epitaxial structure 316b (see FIGS. 2B and 2C) is thus electrically connected to the well region 318. A second area 346b in FIG. 3A is an area where the insulating structure 342 is not present or has an opening formed therein, and a fourth epitaxial structure 316d (see FIGS. 3B and 3C) is thus electrically connected to the well region 318. The first and second areas 346a, 346b may be referred to as non-isolation areas.

In FIG. 3A, a first conductor 330 extends in the second direction to vertically overlap the second area 346b. In FIGS. 3A˜3C, the first conductor 330 is configured as a bitline of the bitcell region 320. The first conductor 330 extends in the second direction at both left-hand and right-hand sides of FIG. 3A. By extending the first conductor 330, bit line connections are provided for at two ends of the first conductor 330, which, as compared to the first conductor 230 for the bitcell region 220 of the semiconductor device 200, enables additional connections, e.g., input/output (I/O) connections, to be made to the bitline and/or provides greater routing flexibility for connections to the bitline.

In FIG. 3A, a reference voltage, e.g., VSS, is provided to the bitcell region 320 by a conductor 339 that extends in the second direction in a location that is generally aligned with wordline conductors 338a, 338b. The conductor 339 is offset in a height direction of the cell, i.e., in the first direction, relative to the bitline. Thus, whereas in FIG. 2A the reference voltage conductor 234 is aligned with the bitline conductor 230 along the second direction, in FIG. 3A the reference voltage conductor 339 is not aligned with the bitline conductor 330 but is instead offset, in the first direction, to be aligned with the wordline conductors 338a, 338b.

In further detail, the reference voltage, e.g., VSS, is provided to the conductor 339. Referring to FIG. 3C, the conductor 339 is electrically connected by a third via 332c, e.g., in the VD layer, to a fourth conductive structure 326d. Thus, the reference voltage is provided to the fourth conductive structure 326d. Referring to FIG. 3B, the fourth conductive structure 326d is electrically connected to a fourth epitaxial structure 316d. A second area 346b in FIG. 3B is an area where the insulating structure 342 is not present or has an opening, and the fourth epitaxial structure 316d is electrically connected to the well region 318. Thus, the reference voltage provided to the fourth conductive structure 326d is electrically connected to the well region 318 by way of the fourth epitaxial structure 316d.

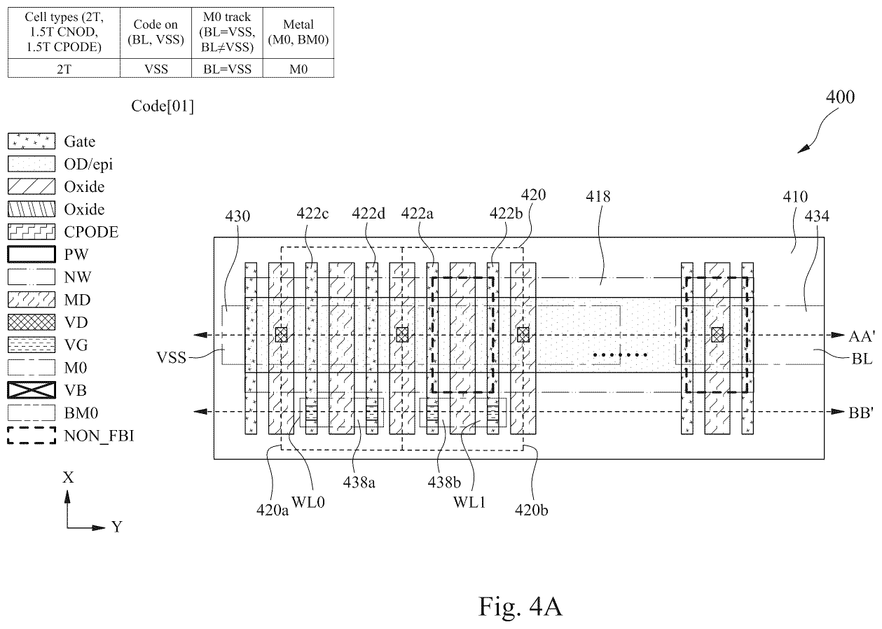

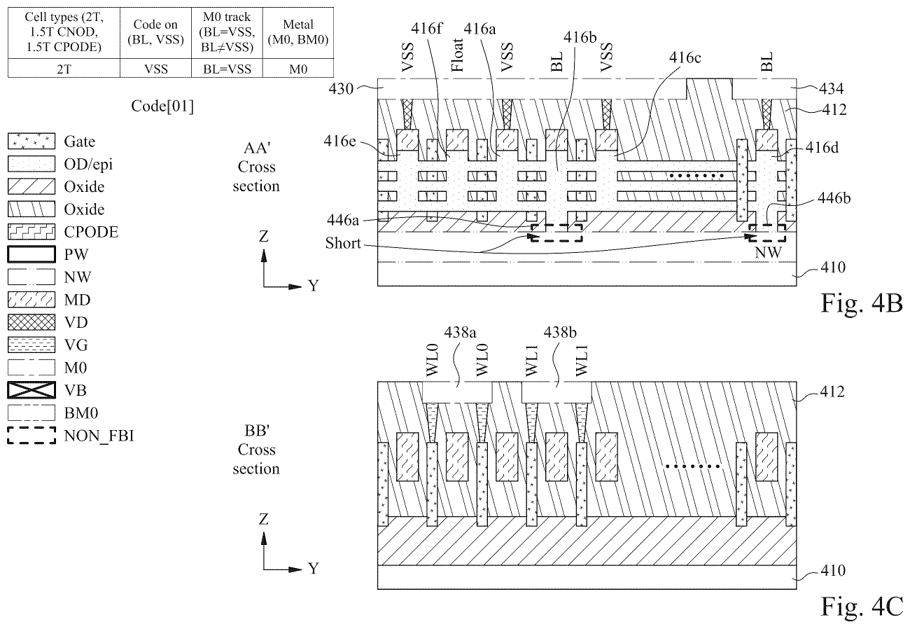

FIG. 4A is a schematic plan view of a semiconductor device 400 according to at least one embodiment, FIG. 4B is a cross-sectional view corresponding to a line A-A′ in FIG. 4A, and FIG. 4C is a cross-sectional view corresponding to a line B-B′ in FIG. 4A.

Elements of the semiconductor device 400 that are similar to elements of the semiconductor device 200 have a corresponding identifying numeral, increased by 200. Aspects of the semiconductor device 400 will be described with reference to the semiconductor device 200 of FIGS. 2A˜2C, i.e., aspects of the semiconductor device 400 that are different from the semiconductor device 200 will be mainly described.

Referring to FIG. 4A, the semiconductor device 400 is an example of a 2T cell type device in which a bitcell region 420 encodes first and second logic values that are different from each other, e.g., [01]. The first logic value, e.g., logic ‘0’, is encoded in a first bitcell 420a. The second logic value, e.g., logic ‘1’, is encoded in a second bitcell 420b. In the semiconductor device 400, the encodings of the first and second logic values correspond to, respectively, electrical disconnections from and electrical connections to a well region 418.

In the semiconductor device 400, a conductor 430 is provided with a reference voltage VSS, whereas the first conductor 230 in the semiconductor device 200 is configured as a bitline. On the other hand, in the semiconductor device 400, a conductor 434 is configured as a bitline, whereas the second conductor 234 in the semiconductor device 200 is provided with the reference voltage VSS. Thus, whereas the semiconductor device 200 is coded on the bitline, the semiconductor device 400 is coded on VSS. Other aspects of the semiconductor device 400 are similar to the semiconductor device 200.

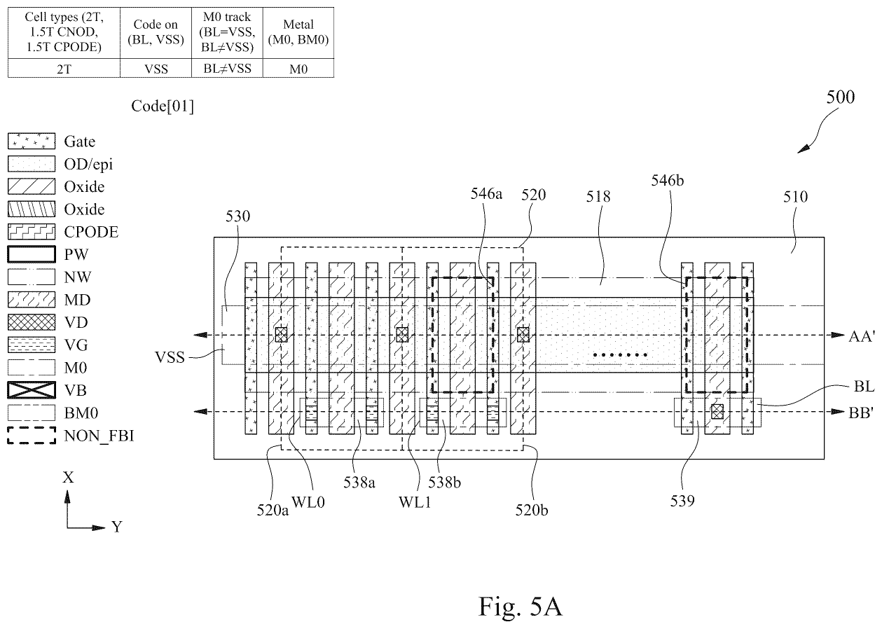

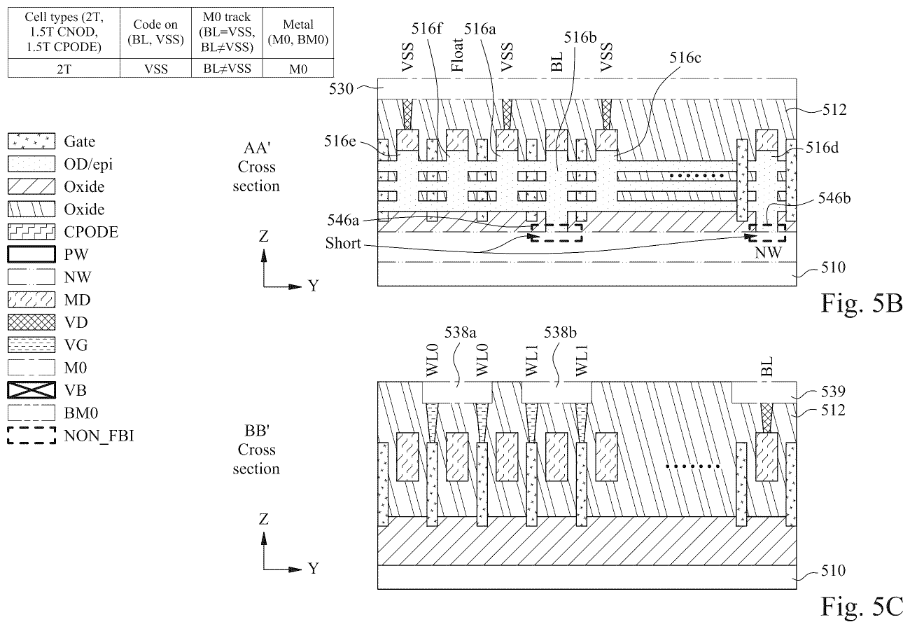

FIG. 5A is a schematic plan view of a semiconductor device 500 according to at least one embodiment, FIG. 5B is a cross-sectional view corresponding to a line A-A′ in FIG. 5A, and FIG. 5C is a cross-sectional view corresponding to a line B-B′ in FIG. 5A.

Elements of the semiconductor device 500 that are similar to elements of the semiconductor device 200 have a corresponding identifying numeral, increased by 300. Aspects of the semiconductor device 500 will be described with reference to the semiconductor device 300 of FIGS. 3A˜3C, i.e., aspects of the semiconductor device 500 that are different from the semiconductor device 300 will be mainly described.

Referring to FIG. 5A, the semiconductor device 500 is an example of a 2T cell type device in which a bitcell region 520 encodes first and second logic values that are different from each other, e.g., [01]. The first logic value, e.g., logic ‘0’, is encoded in a first bitcell 520a. The second logic value, e.g., logic ‘1’, is encoded in a second bitcell 520b. In the semiconductor device 500, the encodings of the first and second logic values correspond to, respectively, electrical disconnections from and electrical connections to a well region 518.

In the semiconductor device 500, a conductor 530 is provided with a reference voltage VSS, whereas the first conductor 330 in the semiconductor device 300 is configured as a bitline. The conductor 530 extends in the second direction at both left-hand and right-hand sides of FIG. 5A, and thus reference voltage connections can be provided at two ends of the conductor 530, which enables additional connections to be made and/or provides greater routing flexibility. On the other hand, in the semiconductor device 500, a conductor 539 is configured as a bitline, whereas the conductor 339 in the semiconductor device 300 is provided with the reference voltage VSS. Thus, whereas the semiconductor device 300 is coded on the bitline, the semiconductor device 500 is coded on VSS. The conductor 539 configured as the bitline is offset in a height direction of the cell, i.e., in the first direction, relative to the conductor 530 providing VSS. Thus, in FIG. 3A the bitline conductor 539 is aligned with wordline conductors 538a, 538b. Other aspects of the semiconductor device 500 are similar to the semiconductor device 300.

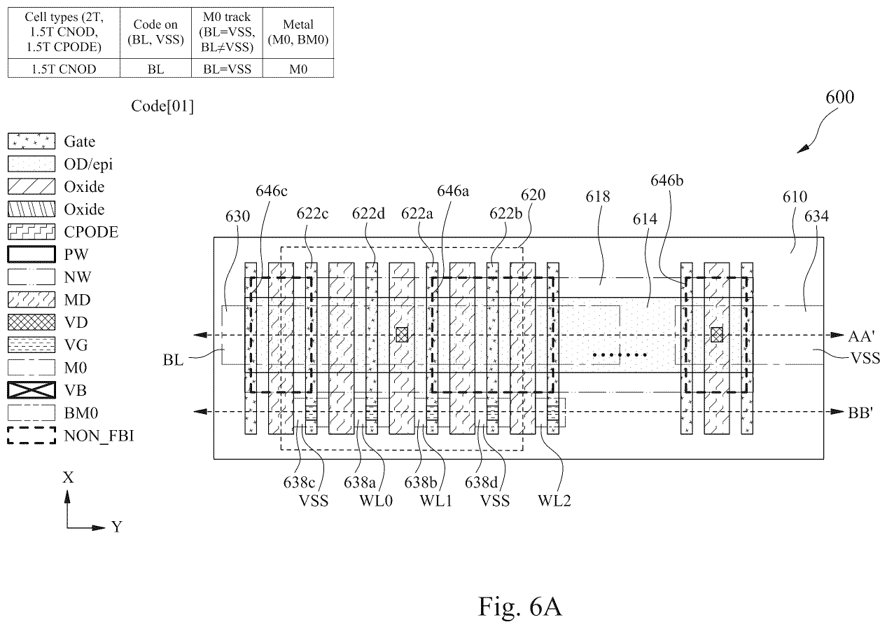

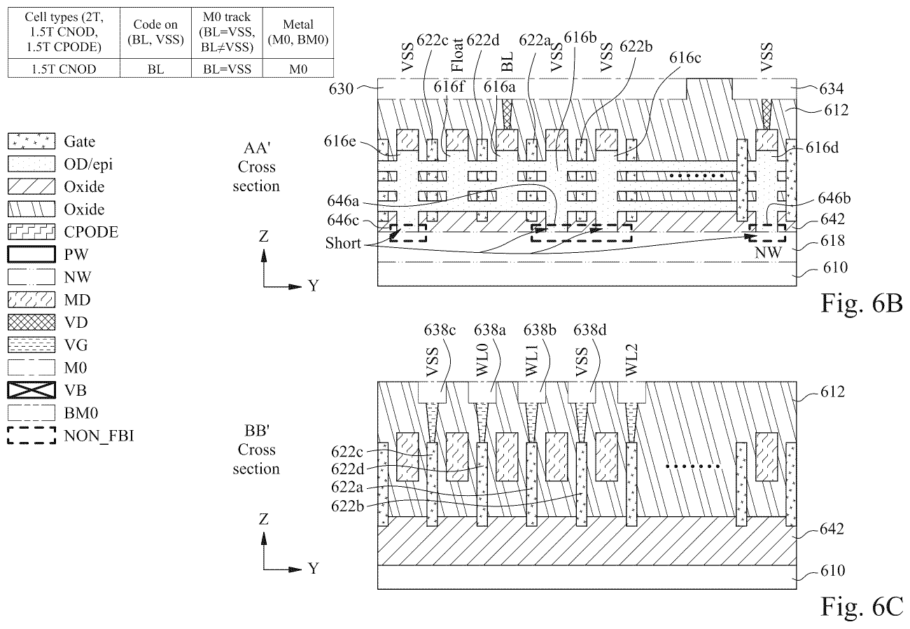

FIG. 6A is a schematic plan view of a semiconductor device 600 according to at least one embodiment, FIG. 6B is a cross-sectional view corresponding to a line A-A′ in FIG. 6A, and FIG. 6C is a cross-sectional view corresponding to a line B-B′ in FIG. 6A.

Elements of the semiconductor device 600 that are similar to elements of the semiconductor device 200 have a corresponding identifying numeral, increased by 400. Aspects of the semiconductor device 600 will be described with reference to the semiconductor device 200 of FIGS. 2A˜2C, i.e., aspects of the semiconductor device 600 that are different from the semiconductor device 200 will be mainly described.

Whereas the semiconductor device 200 is an example of a ROM implemented as a 2T (2 transistor) device, the semiconductor device 600 is an example of a ROM implemented as a 1.5T cell type device with a continuous active area structure. The continuous active area structure may also be referred to as a continuous oxide diffusion or CNOD structure. In some embodiments in which there is a CNOD configuration, an active area pattern is substantially continuous at a side boundary of cell, and a region of an active area pattern overlapping a side boundary of the cell is designated for doping, which results in a filler region in a corresponding semiconductor device. In some embodiments, implementing a ROM device with a CNOD structure reduces a cell width while maintaining a transistor diffusion unbroken, thus providing more uniform strain and/or performance characteristics than a structure in which the transistor diffusion is broken.

Referring to FIG. 6A, the semiconductor device 600 includes a bitcell region 620 encoding a first and second logic values that are different from each other, e.g., [01]. The first logic value, e.g., logic ‘0’, is encoded in a first bitcell 320a. The second logic value, e.g., logic ‘1’, is encoded in a second bitcell 320b. In the semiconductor device 600, the encodings of the first and second logic values correspond to, respectively, electrical disconnections from and electrical connections to a well region 618.

The semiconductor device 600, like the semiconductor device 200, includes a first conductor 630 that extends in the second direction and vertically overlaps an active area 614, and is configured as a bitline. Also, a second conductor 634 extends in the second direction along a same virtual line, or track, as the first conductor 630 and vertically overlaps the active area 614, and is configured to provide VSS. In the semiconductor device 600, the first conductor 630 is electrically connected to a first epitaxial structure 616a whereas, in the semiconductor device 200, the first conductor 230 is electrically connected to the first epitaxial structure 216a as well as the third epitaxial structure 216c and the fifth epitaxial structure 216c. Thus, the semiconductor device 600 has the bitline electrically connected only to the first epitaxial structure 616a among the first through sixth epitaxial structures 616a˜616f.

The semiconductor device 600, like the semiconductor device 200, includes a conductor 638a configured as a first wordline WL0 and a conductor 638b configured as a second wordline WL1. The semiconductor device 600 is configured as a ROM memory in which the bitcell region 620 is encoded with a first logic value, e.g., logic ‘0’, for the first wordline WL0 and encoded with a second logic value, e.g., logic ‘1’, for the second wordline WL1. In the semiconductor device 600, the conductor 638a is electrically connected to one gate structure 622d whereas, in the semiconductor device 200, the conductor 238a is electrically connected to two gate structures 222c, 222d. Also, in the semiconductor device 600, the conductor 638b is electrically connected to one gate structure 622a whereas, in the semiconductor device 200, the conductor 238b is electrically connected to two gate structures 222a, 222b. The semiconductor device 600 further includes (relative to the semiconductor device 200) a conductor 638c electrically connected to gate structure 622c, and a conductor 638d electrically connected to gate structure 622b. The conductor 638c is configured to provide VSS to the gate structure 622c, and the conductor 638d is configured to provide VSS to the gate structure 622d.

As described above, the conductor 638a is configured as the first wordline WL0 and electrically connected to the gate structure 622d, the conductor 638b is configured as the second wordline WL1 and is electrically connected to the gate structure 622a, the conductor 638c is configured to provide VSS and is electrically connected to gate structure 622c, and the conductor 638d is configured to provide VSS and is electrically connected to gate structure 622b. The conductors 638a˜638d are substantially aligned along a same virtual line, or track, in the second direction.

A first area 646a in FIGS. 6A and 6B is an area where an insulating structure 642 is not present or has an opening formed therein, and each of a second epitaxial structure 616b and a third epitaxial structure 616c is thus electrically connected to the well region 618. A second area 646b is an area where the insulating structure 642 is not present or has an opening formed therein, and a fourth epitaxial structure 616d is thus electrically connected to the well region 618. A third area 646c is an area where the insulating structure 642 is not present or has an opening formed therein, and a fifth epitaxial structure 616e is thus electrically connected to the well region 618. Thus, the second epitaxial structure 616b, the third epitaxial structure 616c, the fourth epitaxial structure 616d, and the fifth epitaxial structure 616e are each shorted to the well region 618. The first, second, and third areas 646a˜646c may be referred to as non-isolation areas. A sixth epitaxial structure 616f is electrically floated. In some embodiments, a voltage or signal may be applied to the sixth epitaxial structure 616f.

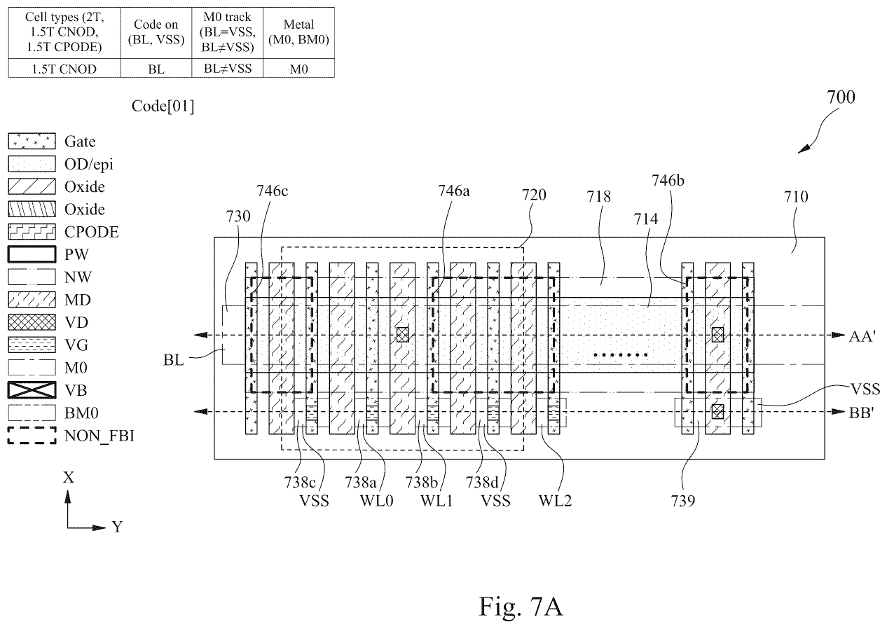

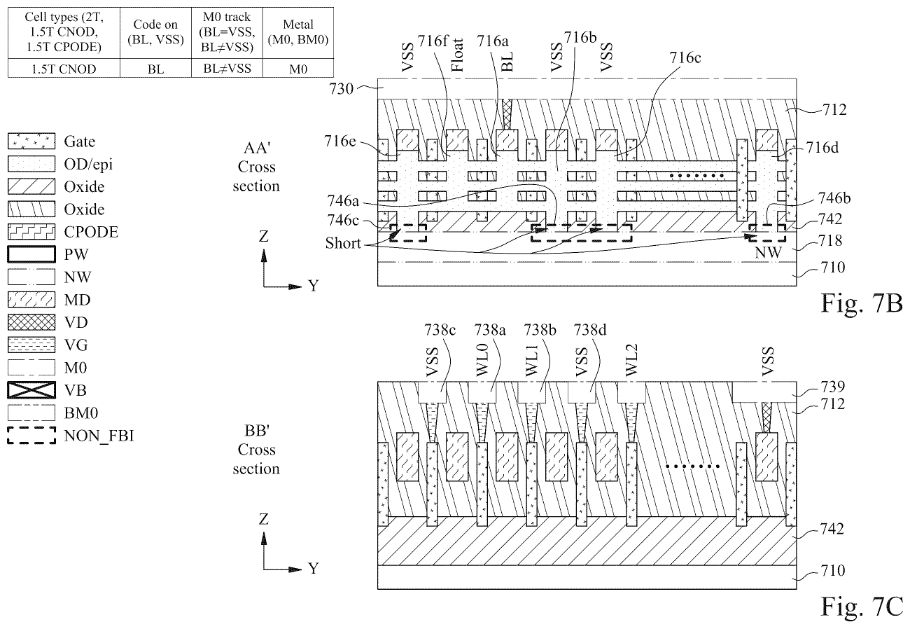

FIG. 7A is a schematic plan view of a semiconductor device 700 according to at least one embodiment, FIG. 7B is a cross-sectional view corresponding to a line A-A′ in FIG. 7A, and FIG. 7C is a cross-sectional view corresponding to a line B-B′ in FIG. 7A.

Elements of the semiconductor device 700 that are similar to elements of the semiconductor device 200 have a corresponding identifying numeral, increased by 500. The semiconductor device 700 includes features of the semiconductor devices 300 and 600.

The semiconductor device 700 is an example of a ROM implemented as a 1.5T cell type device with a CNOD structure, similar to the semiconductor device 600. In the semiconductor device 700, a bitcell region 720 encodes first and second logic values that are different from each other, e.g., [01]. In the semiconductor device 700, the encodings of the first and second logic values correspond to, respectively, electrical disconnections from and electrical connections to a well region 718.

Also, similar to the semiconductor device 300, the semiconductor device 700 includes a conductor 730 that extends in the second direction at both left-hand and right-hand sides of FIG. 7A. By extending the conductor 730, bit line connections are provided for at two ends of the conductor 730, which enables additional connections to be made to the bitline and/or provides greater routing flexibility for connections to the bitline. Also, similar to the semiconductor device 300, in the semiconductor device 700, VSS is provided to a bitcell region 720 by a conductor 739 that extends in the second direction in a location that is generally aligned with wordline conductors 738a, 738b and VSS conductors 738c, 738d, the conductor 739 being offset in a height direction of the cell, i.e., in the first direction, relative to the bitline conductor 730.

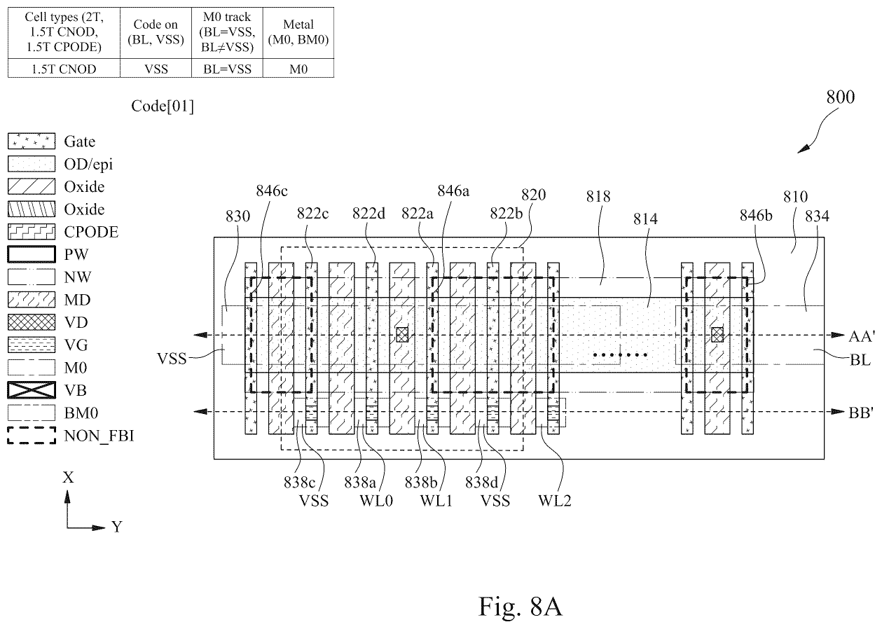

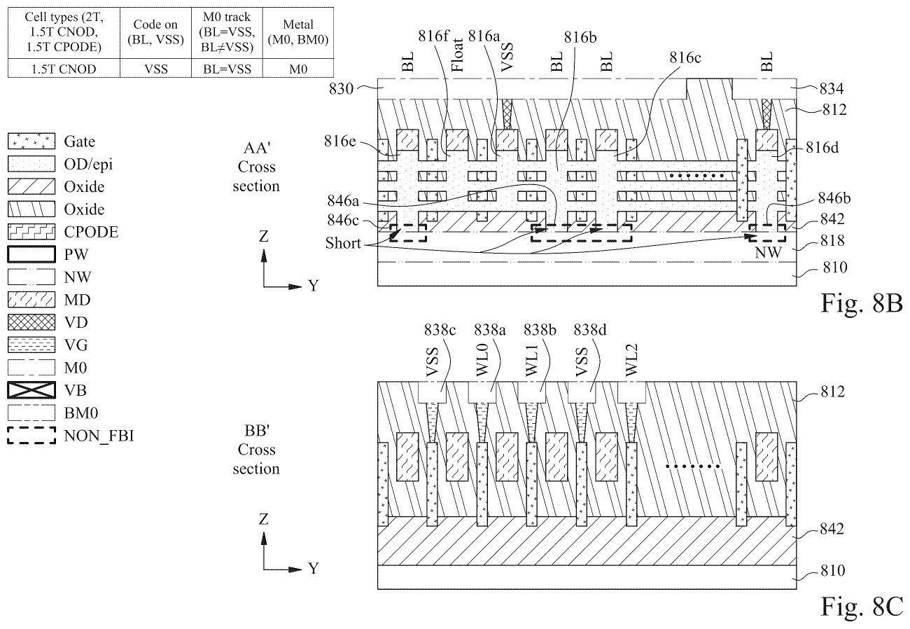

FIG. 8A is a schematic plan view of a semiconductor device 800 according to at least one embodiment, FIG. 8B is a cross-sectional view corresponding to a line A-A′ in FIG. 8A, and FIG. 8C is a cross-sectional view corresponding to a line B-B′ in FIG. 8A.

Elements of the semiconductor device 800 that are similar to elements of the semiconductor device 200 have a corresponding identifying numeral, increased by 600. The semiconductor device 800 includes features of the semiconductor devices 400 and 600.

The semiconductor device 800 is an example of a ROM implemented as a 1.5T cell type device with a CNOD structure, similar to the semiconductor device 600. In the semiconductor device 800, a bitcell region 820 encodes first and second logic values that are different from each other, e.g., [01]. In the semiconductor device 800, the encodings of the first and second logic values correspond to, respectively, electrical disconnections from and electrical connections to a well region 818.

Also, similar to the semiconductor device 400, the semiconductor device 800 includes a conductor 830 that provides a reference voltage VSS. Also, similar to the semiconductor device 400, in the semiconductor device 800, a conductor 834 is configured as a bitline. Thus, like the semiconductor device 400, the semiconductor device 800 is coded on VSS. The conductor 830 and the conductor 834 are substantially centered along a same virtual line, or track, extending in the second direction.

The semiconductor device 800, like the semiconductor device 400, includes a conductor 838a configured as a first wordline WL0 and a conductor 838b configured as a second wordline WL1. The semiconductor device 800 is configured as a ROM memory in which the bitcell region 820 is encoded with a first logic value, e.g., logic ‘0’, for the first wordline WL0 and encoded with a second logic value, e.g., logic ‘1’, for the second wordline WL1. In the semiconductor device 800, the conductor 838a is electrically connected to one gate structure 822d whereas, in the semiconductor device 400, the conductor 438a is electrically connected to two gate structures 422c, 422d. Also, in the semiconductor device 800, the conductor 838b is electrically connected to one gate structure 822a whereas, in the semiconductor device 400, the conductor 438b is electrically connected to two gate structures 422a, 422b. The semiconductor device 800 further includes (relative to the semiconductor device 400) a conductor 838c electrically connected to gate structure 822c, and a conductor 838d electrically connected to gate structure 822b. The conductor 838c is configured to provide VSS to the gate structure 822c, and the conductor 838d is configured to provide VSS to the gate structure 822d.

As described above, the conductor 838a is configured as the first wordline WL0 and electrically connected to the gate structure 822d, the conductor 838b is configured as the second wordline WL1 and is electrically connected to the gate structure 822a, the conductor 838c is configured to provide VSS and is electrically connected to gate structure 822c, and the conductor 838d is configured to provide VSS and is electrically connected to gate structure 822b. The conductors 838a˜838d are substantially aligned along a same virtual line, or track, in the second direction.

The heights of the conductor 830 and the conductor 834 are greater than the height of a third conductor 838 in the second direction. Increasing the height of the conductor 830 and/or the conductor 834 helps to reduce resistance of the conductor 830 and/or the conductor 834, while reducing the heights of the conductors 838a˜838d helps to maintain clearance in the first direction between the conductor 830 and the conductors 838a˜838d and helps to reduce die area. In at least one embodiment such as the embodiment of FIGS. 8A˜8C in which the conductor 830 is configured as to provide VSS, increasing the height of the conductor 830 helps to reduce resistance of the supply of VSS.

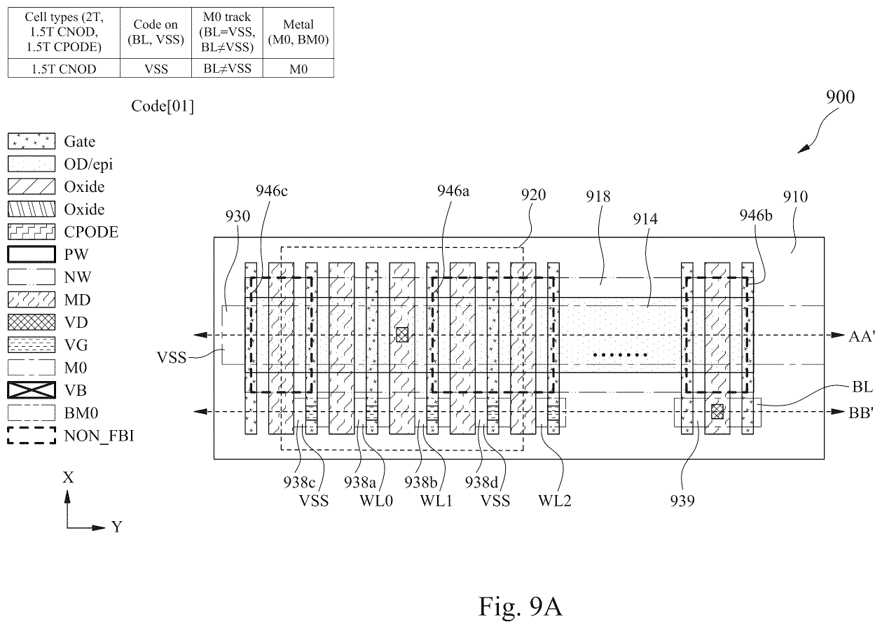

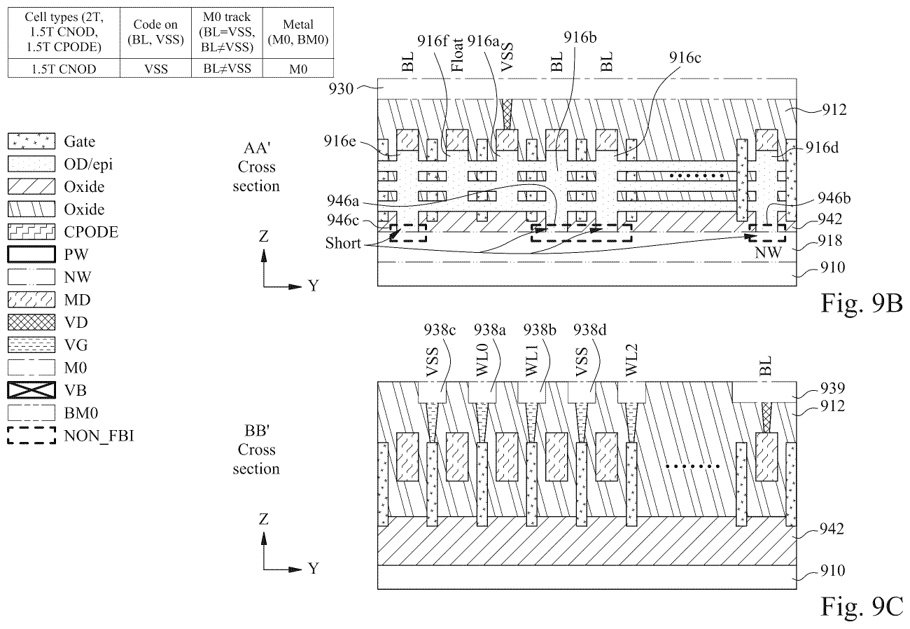

FIG. 9A is a schematic plan view of a semiconductor device 900 according to at least one embodiment, FIG. 9B is a cross-sectional view corresponding to a line A-A′ in FIG. 9A, and FIG. 9C is a cross-sectional view corresponding to a line B-B′ in FIG. 9A.

Elements of the semiconductor device 900 that are similar to elements of the semiconductor device 200 have a corresponding identifying numeral, increased by 700. The semiconductor device 900 includes features of the semiconductor devices 500 and 600.

The semiconductor device 900 is an example of a ROM implemented as a 1.5T cell type device with a CNOD structure, similar to the semiconductor device 600. In the semiconductor device 900, a bitcell region 920 encodes first and second logic values that are different from each other, e.g., [01]. In the semiconductor device 900, the encodings of the first and second logic values correspond to, respectively, electrical disconnections from and electrical connections to a well region 918.

Also, similar to the semiconductor device 500, the semiconductor device 900 includes a conductor 930 that provides a reference voltage VSS and extends in the second direction at both left-hand and right-hand sides of FIG. 9A, which enables reference voltage connections to be provided at two ends of the conductor 930 and which enables additional connections to be made and/or provides greater routing flexibility. Like the semiconductor device 500, the semiconductor device 900 is coded on VSS.

Also, similar to the semiconductor device 500, the semiconductor device 900 includes a conductor 939 configured as a bitline. The conductor 939 configured as the bitline is offset in a height direction of the cell, i.e., in the first direction, relative to the conductor 930 providing VSS. Thus, in FIG. 9A the bitline conductor 939 is aligned with a conductor 938a configured as the first wordline WL0, a conductor 938b configured as the second wordline WL1, a conductor 938c configured to provide VSS, and a conductor 938d configured to provide VSS.

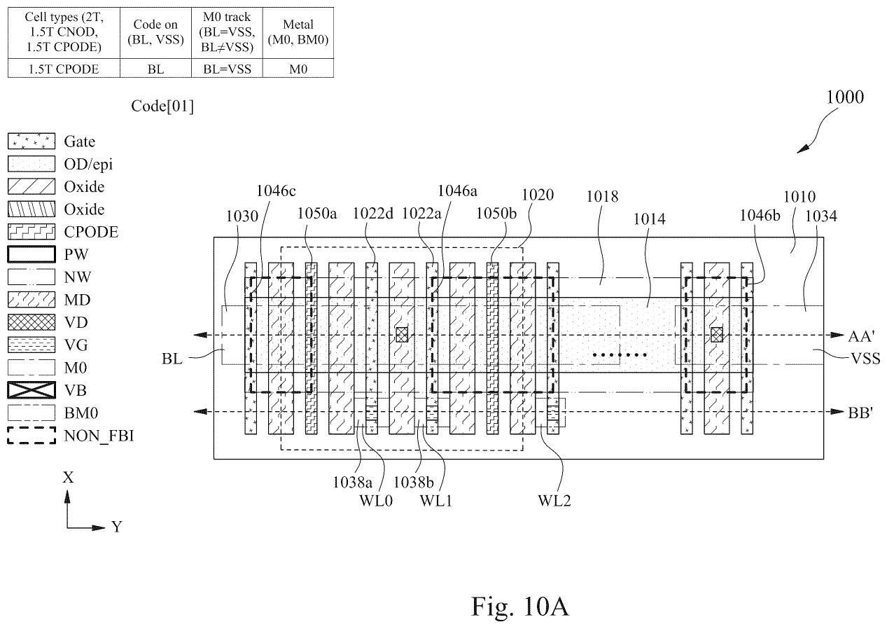

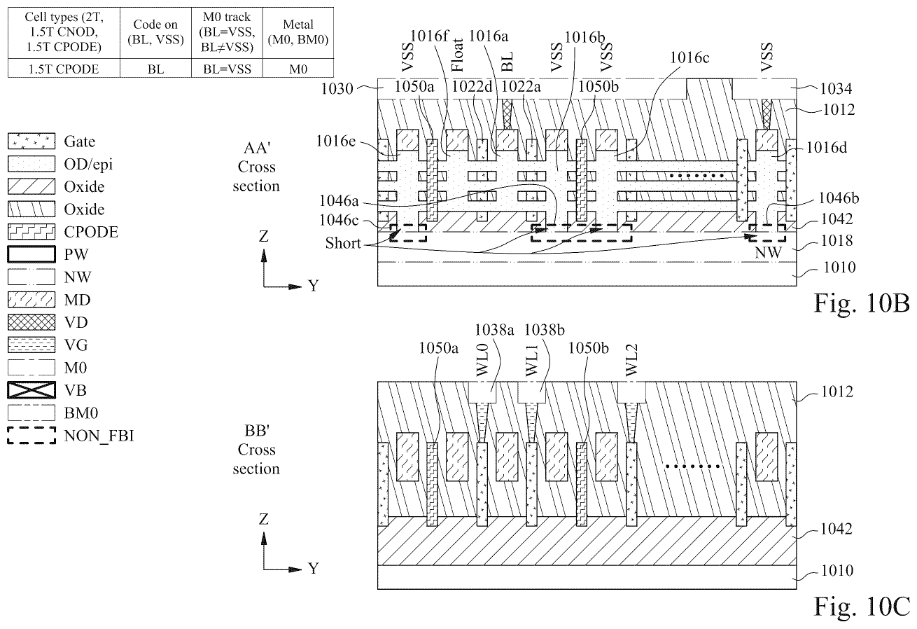

FIG. 10A is a schematic plan view of a semiconductor device 1000 according to at least one embodiment, FIG. 10B is a cross-sectional view corresponding to a line A-A′ in FIG. 10A, and FIG. 10C is a cross-sectional view corresponding to a line B-B′ in FIG. 10A.

Elements of the semiconductor device 1000 that are similar to elements of the semiconductor device 200 have a corresponding identifying numeral, increased by 800. The semiconductor device 1000 includes features of the semiconductor devices 200 and 600.

The semiconductor device 1000 is an example of a ROM implemented as a 1.5T cell type device with a continuous poly over diffusion edge (CPODE) structure. In some embodiments in which there is a CPODE configuration, an active area pattern is substantially discontinuous at a side boundary of cell and an insulator pattern is disposed over a region representing a break in the active area pattern at the side boundary of the cell. In some embodiments, implementing a ROM device with a CPODE structure to isolate neighboring active regions helps to scale or reduce the CPP or center-to-center distance along the second direction between two immediately-adjacent gate regions, resulting in an overall improvement in circuit density.

Referring to FIG. 10A, the semiconductor device 1000 includes a bitcell region 1020 encoding a first and second logic values that are different from each other, e.g., [01]. In the semiconductor device 1000, the encodings of the first and second logic values correspond to, respectively, electrical disconnections from and electrical connections to a well region 1018.

The semiconductor device 1000, like the semiconductor device 200, includes a first conductor 1030 that extends in the second direction and vertically overlaps an active area 1014, and is configured as a bitline. Also, a second conductor 1034 extends in the second direction along a same virtual line, or track, as the first conductor 1030 and vertically overlaps the active area 1014, and is configured to provide VSS. In the semiconductor device 1000, the first conductor 1030 is electrically connected to a first epitaxial structure 1016a whereas, in the semiconductor device 200, the first conductor 230 is electrically connected to the first epitaxial structure 216a as well as the third epitaxial structure 216c and the fifth epitaxial structure 216c. Thus, the semiconductor device 1000 has the bitline electrically connected only to the first epitaxial structure 1016a among the first through sixth epitaxial structures 1016a˜1016c.

The semiconductor device 1000, like the semiconductor device 200, includes a conductor 1038a configured as a first wordline WL0 and a conductor 1038b configured as a second wordline WL1. The semiconductor device 600 is configured as a ROM memory in which the bitcell region 1020 is encoded with a first logic value, e.g., logic ‘0’, for the first wordline WL0 and encoded with a second logic value, e.g., logic ‘1’, for the second wordline WL1. In the semiconductor device 1000, the conductor 1038a is electrically connected to one gate structure 1022d whereas, in the semiconductor device 200, the conductor 238a is electrically connected to two gate structures 222c, 222d. Also, in the semiconductor device 1000, the conductor 1038b is electrically connected to one gate structure 1022a whereas, in the semiconductor device 200, the conductor 238b is electrically connected to two gate structures 222a, 222b.

As described above, the conductor 1038a is configured as the first wordline WL0 and electrically connected to the gate structure 1022d, and the conductor 1038b is configured as the second wordline WL1 and is electrically connected to the gate structure 1022a. The conductors 1038a, 1038b are substantially aligned along a same virtual line, or track, in the second direction.

A first area 1046a in FIGS. 10A and 10B is an area where an insulating structure 1042 is not present or has an opening formed therein, and each of a second epitaxial structure 1016b and a third epitaxial structure 1016c is thus electrically connected to the well region 1018. A second area 1046b is an area where the insulating structure 1042 is not present or has an opening formed therein, and a fourth epitaxial structure 1016d is thus electrically connected to the well region 1018. A third area 1046c is an area where the insulating structure 1042 is not present or has an opening formed therein, and a fifth epitaxial structure 1016e is thus electrically connected to the well region 1018. Thus, the second epitaxial structure 1016b, the third epitaxial structure 1016c, the fourth epitaxial structure 1016d, and the fifth epitaxial structure 1016e are each shorted to the well region 1018. The first, second, and third areas 1046a˜1046c may be referred to as non-isolation areas. A sixth epitaxial structure 1016f is electrically floated. In some embodiments, a voltage or signal may be applied to the sixth epitaxial structure 1016f.

As compared to the semiconductor device 600, the semiconductor device 1000 includes a first CPODE pattern 1050a between the fifth epitaxial structure 1016e and the sixth epitaxial structure 1016f, whereas the semiconductor device 600 includes the gate structure 622c between the fifth epitaxial structure 616e and the sixth epitaxial structure 616f. Also, the semiconductor device 1000 includes a second CPODE pattern 1050b between a second epitaxial structure 1016b and a third epitaxial structure 1016c, whereas the semiconductor device 600 includes the gate structure 622b between the second epitaxial structure 616b and the third epitaxial structure 616c. In some embodiments, the first and second CPODE patterns 1050a, 1050b include a dielectric material, e.g., one or more of silicon nitride, silicon oxynitride, silicon carbon nitride, silicon oxycarbonitride, oxygen-doped silicon carbonitride, silicon oxide, or the like. In some embodiments, the CPODE patterns are formed by removing a gate, e.g., a dummy gate, and depositing one or more dielectric materials.

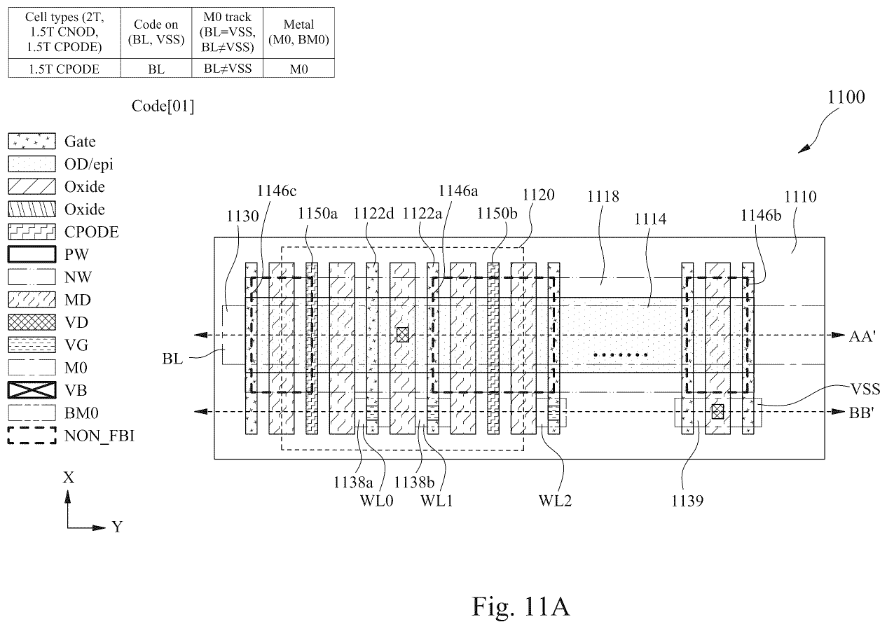

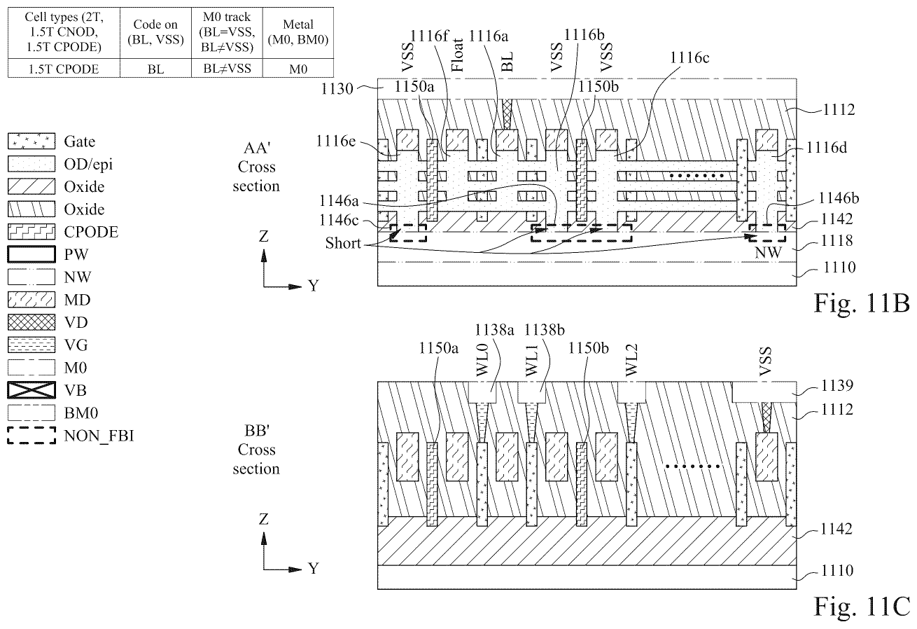

FIG. 11A is a schematic plan view of a semiconductor device 1100 according to at least one embodiment, FIG. 11B is a cross-sectional view corresponding to a line A-A′ in FIG. 11A, and FIG. 11C is a cross-sectional view corresponding to a line B-B′ in FIG. 11A.

Elements of the semiconductor device 1100 that are similar to elements of the semiconductor device 200 have a corresponding identifying numeral, increased by 900. The semiconductor device 1100 includes features of the semiconductor devices 300 and 1000.

The semiconductor device 1100 is an example of a ROM implemented as a 1.5T cell type device with a CPODE structure, similar to the semiconductor device 1000. In the semiconductor device 1100, a bitcell region 1120 encodes first and second logic values that are different from each other, e.g., [01]. In the semiconductor device 1100, the encodings of the first and second logic values correspond to, respectively, electrical disconnections from and electrical connections to a well region 1118.

Also, similar to the semiconductor device 300, the semiconductor device 1100 includes a conductor 1130 that extends in the second direction at both left-hand and right-hand sides of FIG. 11A. By extending the conductor 1130, bit line connections are provided for at two ends of the conductor 1130, which enables additional connections to be made to the bitline and/or provides greater routing flexibility for connections to the bitline. Also, similar to the semiconductor device 300, in the semiconductor device 1100, VSS is provided to a bitcell region 1120 by a conductor 1139 that extends in the second direction in a location that is generally aligned with wordline conductors 1138a, 1138b, the conductor 1139 being offset in a height direction of the cell, i.e., in the first direction, relative to the bitline conductor 1130.

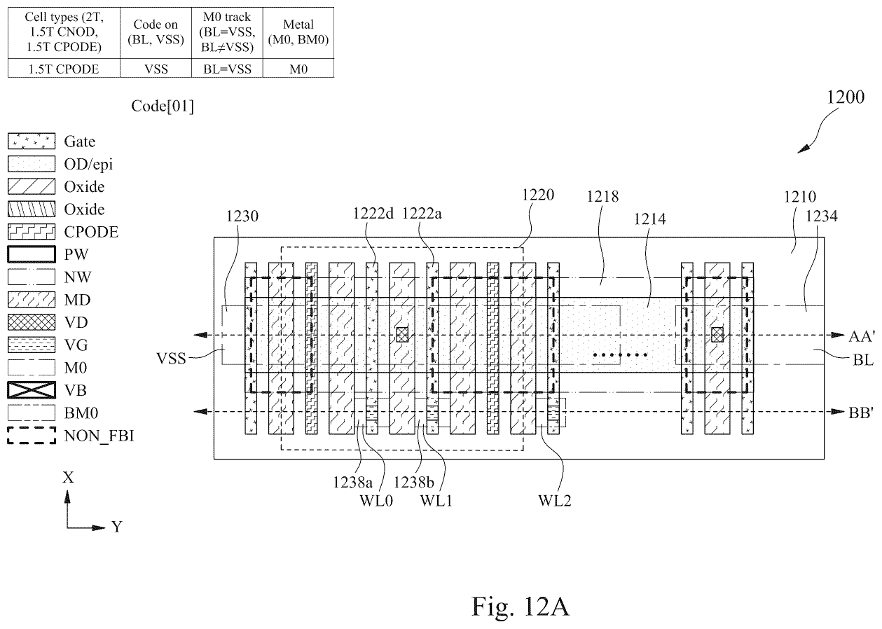

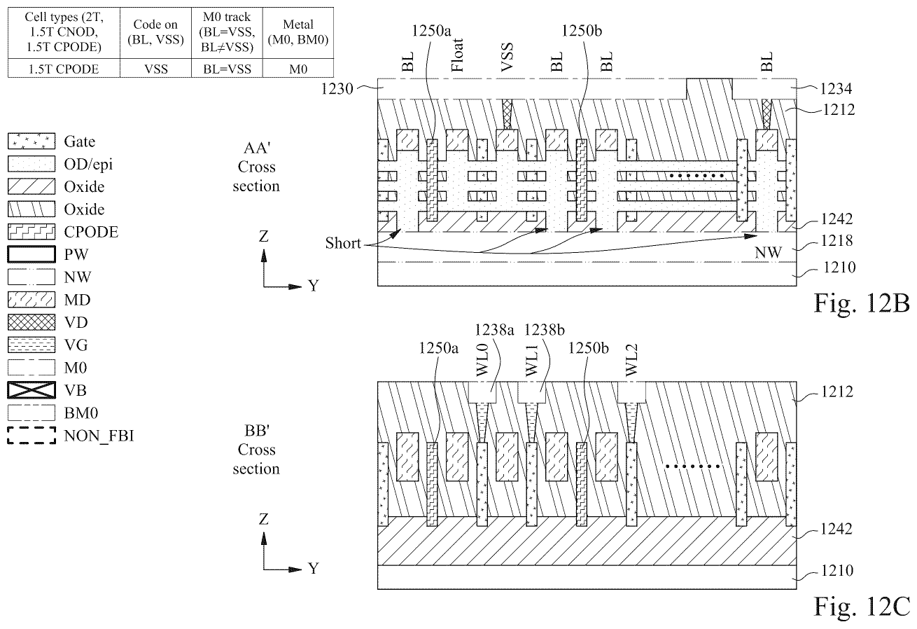

FIG. 12A is a schematic plan view of a semiconductor device 1200 according to at least one embodiment, FIG. 12B is a cross-sectional view corresponding to a line A-A′ in FIG. 12A, and FIG. 12C is a cross-sectional view corresponding to a line B-B′ in FIG. 12A.

Elements of the semiconductor device 1200 that are similar to elements of the semiconductor device 200 have a corresponding identifying numeral, increased by 1000. The semiconductor device 1200 includes features of the semiconductor devices 400 and 1000.

The semiconductor device 1200 is an example of a ROM implemented as a 1.5T cell type device with a CPODE structure, similar to the semiconductor device 1000. In the semiconductor device 1200, a bitcell region 1220 encodes first and second logic values that are different from each other, e.g., [01]. In the semiconductor device 1200, the encodings of the first and second logic values correspond to, respectively, electrical disconnections from and electrical connections to a well region 1218.

Also, similar to the semiconductor device 400, the semiconductor device 1200 includes a conductor 1230 that provides a reference voltage VSS. Also, similar to the semiconductor device 400, in the semiconductor device 800, a conductor 834 is configured as a bitline. Thus, like the semiconductor device 400, the semiconductor device 800 is coded on VSS. The conductor 1230 and the conductor 1234 are substantially centered along a same virtual line, or track, extending in the second direction.

The semiconductor device 1200, like the semiconductor device 400, includes a conductor 1238a configured as a first wordline WL0 and a conductor 1238b configured as a second wordline WL1. The semiconductor device 1200 is configured as a ROM memory in which the bitcell region 1220 is encoded with a first logic value, e.g., logic ‘0’, for the first wordline WL0 and encoded with a second logic value, e.g., logic ‘1’, for the second wordline WL1. In the semiconductor device 1200, the conductor 1238a is electrically connected to one gate structure 1222d whereas, in the semiconductor device 400, the conductor 438a is electrically connected to two gate structures 422c, 422d. Also, in the semiconductor device 1200, the conductor 1238b is electrically connected to one gate structure 1222a whereas, in the semiconductor device 400, the conductor 438b is electrically connected to two gate structures 422a, 422b. The conductors 1238a, 1238d are substantially aligned along a same virtual line, or track, in the second direction.

The heights of the conductor 1230 and the conductor 1234 are greater than the height of the conductor 1238a, 1238b in the second direction. Increasing the height of the conductor 1230 and/or the conductor 1234 helps to reduce resistance on the conductor 1230 and/or the conductor 1234, while reducing the heights of the conductors 1238a, 1238b helps to maintain clearance in the first direction between the first conductor 1230 and the conductors 1238a, 1238b and helps to reduce die area. In at least one embodiment such as the embodiment of FIGS. 12A˜12C in which the first conductor 1230 is configured as to provide VSS, increasing the height of the first conductor 1230 helps to reduce resistance of supply of VSS.

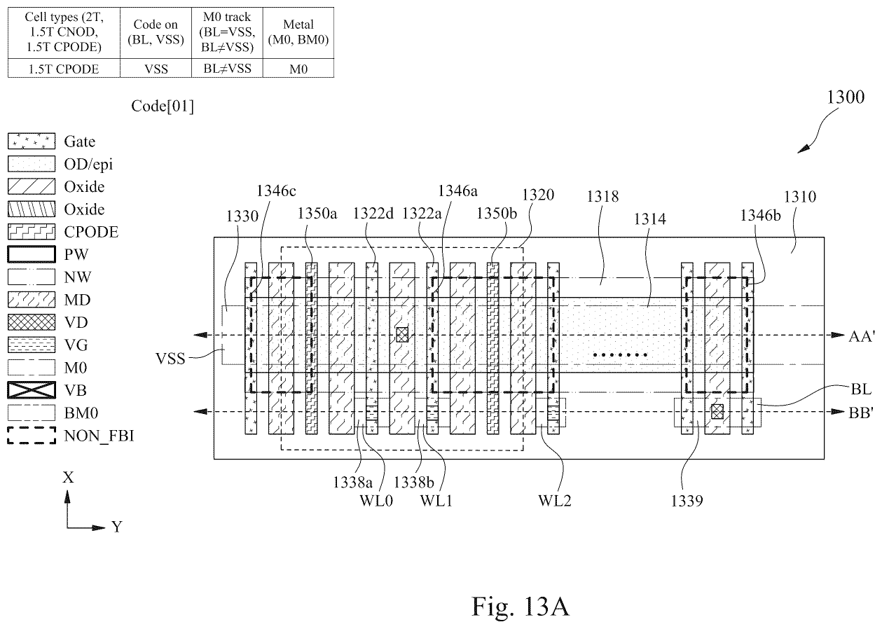

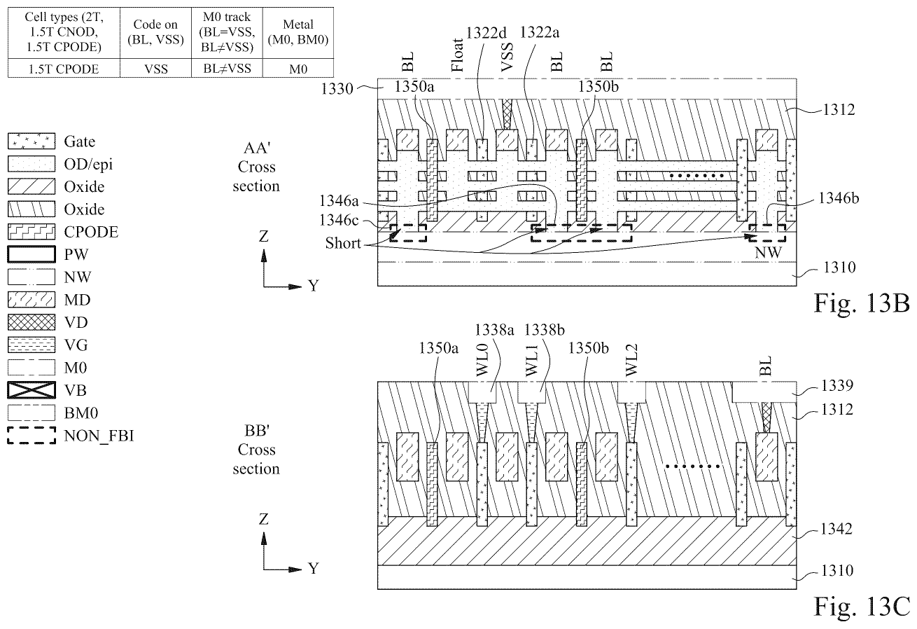

FIG. 13A is a schematic plan view of a semiconductor device 1300 according to at least one embodiment, FIG. 13B is a cross-sectional view corresponding to a line A-A′ in FIG. 13A, and FIG. 13C is a cross-sectional view corresponding to a line B-B′ in FIG. 13A.

Elements of the semiconductor device 1300 that are similar to elements of the semiconductor device 200 have a corresponding identifying numeral, increased by 1100. The semiconductor device 1200 includes features of the semiconductor devices 500 and 1000.

The semiconductor device 1300 is an example of a ROM implemented as a 1.5T cell type device with a CPODE structure, similar to the semiconductor device 1000. In the semiconductor device 1300, a bitcell region 1320 encodes first and second logic values that are different from each other, e.g., [01]. In the semiconductor device 1300, the encodings of the first and second logic values correspond to, respectively, electrical disconnections from and electrical connections to a well region 1318.

Also, similar to the semiconductor device 500, the semiconductor device 1300 includes a conductor 1330 that provides a reference voltage VSS and extends in the second direction at both left-hand and right-hand sides of FIG. 13A, which enables reference voltage connections to be provided at two ends of the conductor 1330 and which enables additional connections to be made and/or provides greater routing flexibility. Like the semiconductor device 500, the semiconductor device 1300 is coded on VSS.

Also, similar to the semiconductor device 500, the semiconductor device 1300 includes a conductor 1339 configured as a bitline. The conductor 1339 configured as the bitline is offset in a height direction of the cell, i.e., in the first direction, relative to the conductor 1330 providing VSS. Thus, in FIG. 13A the bitline conductor 1339 is aligned with a conductor 1338a configured as the first wordline WL0 and a conductor 1338b configured as the second wordline WL1.

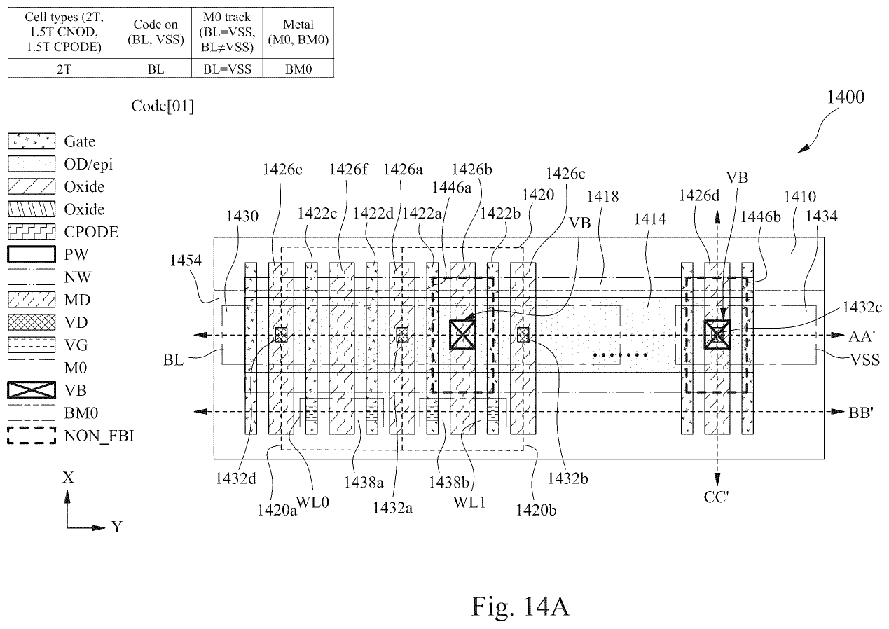

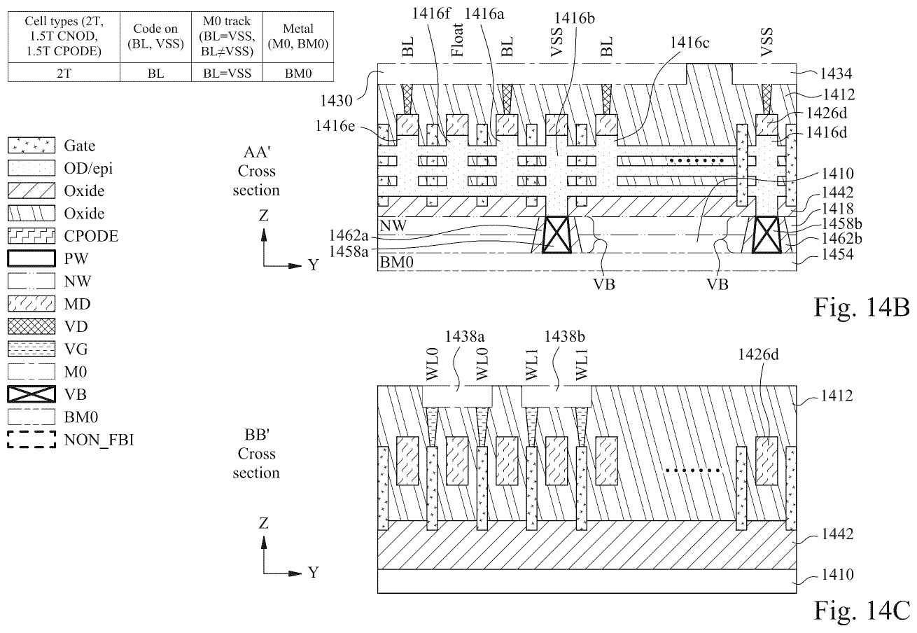

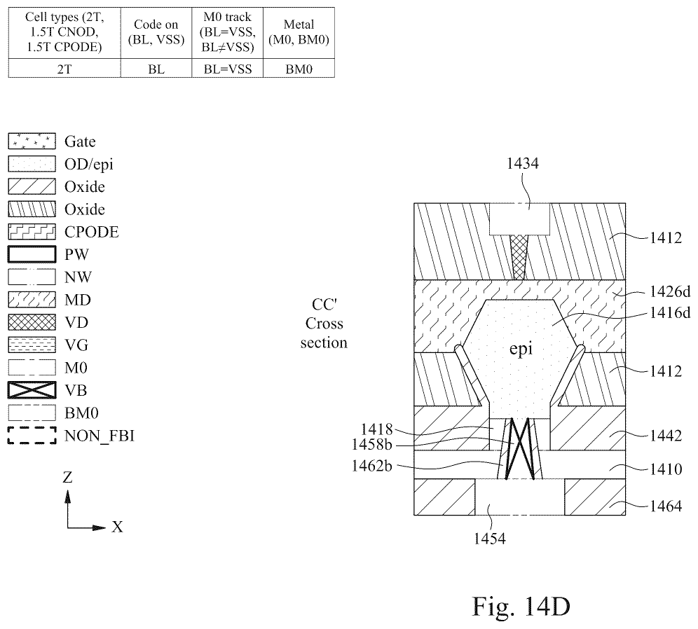

FIG. 14A is a schematic plan view of a semiconductor device 1400 according to at least one embodiment, FIG. 14B is a cross-sectional view corresponding to a line A-A′ in FIG. 14A, FIG. 14C is a cross-sectional view corresponding to a line B-B′ in FIG. 14A, and FIG. 14D is a cross-sectional view corresponding to a line C-C′ in FIG. 14A.

Elements of the semiconductor device 1400 that are similar to elements of the semiconductor device 200 have a corresponding identifying numeral, increased by 1200. Aspects of the semiconductor device 1400 will be described with reference to the semiconductor device 200 of FIGS. 2A˜2C, i.e., aspects of the semiconductor device 1400 that are different from the semiconductor device 200 will be mainly described.

Referring to FIG. 14A, the semiconductor device 1400 is an example of a 2T cell type device (2T=two transistor) in which a bitcell region 1420 encodes first and second logic values that are different from each other, e.g., [01]. The first logic value, e.g., logic ‘0’, is encoded in a first bitcell 1420a. The second logic value, e.g., logic ‘1’, is encoded in a second bitcell 1420b. In the semiconductor device 1400, the encodings of the first and second logic values correspond to, respectively, electrical disconnections from and electrical connections to a well region 1418.

In the semiconductor device 1400, a first conductor 1430 extends in the second direction and vertically overlaps an active area 1414, and is configured as a bitline. Also, a second conductor 1434 extends in the second direction along a same virtual line, or track, as the first conductor 1430 and vertically overlaps the active area 1414, and is configured to provide VSS. The first conductor 1430 is electrically connected to a first epitaxial structure 1416a (by via 1432a and conductive structure 1426a), a third epitaxial structure 1416c (by via 1432b and conductive structure 1426c), and a fifth epitaxial structure 1416e (by via 1432d and conductive structure 1426c).

A first area 1446a in FIG. 14A is an area where an insulating structure 1442 (see FIGS. 14B˜14D) is not present or has an opening formed therein, and an epitaxial structure 1416b (see FIGS. 14B˜14D) is electrically connected to a backside conductor 1454 by a backside via 1458a. The backside via 1458a passes through the well region 1418 and the substrate 1410, and is insulated from the well region 1418 and the substrate 1410 by an insulating structure 1462a. A second area 1446b in FIG. 14A is an area where the insulating structure 1442 is not present or has an opening formed therein, and an epitaxial structure 1416d (see FIGS. 14B˜14D) is electrically connected to the backside conductor 1454 by a backside via 1458b. The backside via 1458b passes through the well region 1418 and the substrate 1410, and is insulated from the well region 1418 and the substrate 1410 by an insulating structure 1462b. Connecting the epitaxial structure 1416b and the epitaxial structure 1416d together using the backside conductor 1454 allows for a reduction in the number of conductors in a metal layer, e.g., an M0 layer, and thus provides layout flexibility such as enabling the use of wider, lower-resistance conductors for a bitline or the like, and/or enabling a reduction in overall cell height. The first and second areas 1446a, 1446b may be referred to as non-isolation areas.

Thus, whereas the semiconductor device 200 electrically connects the second epitaxial structure 216b and the fourth epitaxial structure 216d to the well region 218 and uses the well region as a conductor for VSS, the semiconductor device 1400 electrically connects the epitaxial structure 1416b and the epitaxial structure 1416d to the backside conductor 1454 and uses the backside conductor 1454 as a conductor for VSS. In some embodiments, using the backside conductor 1454 instead of the well region 1418 provides for a lower resistance connection between the epitaxial structure 1416b and the epitaxial structure 1416d, relative to using the well region 1418, and/or provides greater routing flexibility relative to using the well region 1418.

The backside conductor 1454 includes one or more conductive materials, e.g., one or metals such as aluminum, copper, nickel, silver, tin, titanium, tungsten, or the like. In FIGS. 14B˜14D, the backside conductor 1454 is in a first metal layer on a backside of substrate, i.e., BM0, but in other embodiments the backside conductor 1454 is in another backside metal layer, e.g., BM1, BM2, or the like, or in another conductive layer. The backside conductor 1454 is embedded in an insulating structure 1464. In some embodiments, the insulating structure 1464 includes a plurality of insulating layers or structures formed of a same or different insulating materials. In some embodiments, the insulating structure 1464 is or includes an oxide layer. In some embodiments, the insulating structure 142 includes a dielectric material, e.g., one or more of silicon oxide, silicon nitride, SiOCN, or the like. In some embodiments, the dielectric material is formed by a process that includes one or more of atomic layer deposition, chemical vapor deposition, physical vapor deposition, or the like.

The epitaxial structure 1416b is electrically connected to the backside conductor 1454 and thus to the reference voltage VSS supplied to the frontside second conductor 1434. Accordingly, the second bitcell 1420b encodes a first logic value, e.g., logic ‘1’. Stated another way, the presence of the non-isolation area of the first area 1446a where the epitaxial structure 1416b is on the well region 1418 and the electrical connection by way of the backside via 1458a to the backside conductor 1454 means that the epitaxial structure 1416b is electrically connected to VSS and the second bitcell 1420b encodes a first logic value, e.g., logic ‘1’.

On the other hand, in the first bitcell 1420a, the non-isolation area is absent under the fifth epitaxial structure 1416e (see FIGS. 14B˜14D), i.e., the insulating structure 1442 is present under the fifth epitaxial structure 1416e, such that the fifth epitaxial structure 1416e is not electrically connected to the well region 1418 or to the backside conductor 1454, and thus the first bitcell 1420a encodes a second logic value, e.g., a logic ‘0’. Stated another way, the absence of a non-isolation area where the fifth epitaxial structure 1416e is on the well region 1418 means that the fifth epitaxial structure 1416e is electrically disconnected from the well region 1418 and the backside conductor 1454, and thus the first bitcell 1420a encodes a second logic value, e.g., a logic ‘0’. In FIGS. 14A˜14D, the epitaxial structure 1416f is electrically floated. In some embodiments, a voltage or signal may be applied to the epitaxial structure 1416f.

In FIGS. 14A˜14D, conductor 1438a is electrically connected to gate structures 1422c, 1422d, and is configured as a first wordline WL0. Conductor 1438b is electrically connected to gate structures 1422a, 1422b, and is configured as a second wordline WL1. The conductors 1438a, 1438b are substantially aligned along a same virtual line, or track, in the second direction.

In various embodiments, the backside conductor 1454 of the semiconductor device 1400 is implemented in one or more of the semiconductor devices 100˜1300. For example, any one or more of the semiconductor devices 100, 200, 300, 400, 500, 600, 700, 800, 900, 1000, 1100, 1200, and/or 1300 can be implemented using a backside conductor like the backside conductor 1454 in one or more backside metal layers, e.g., BM0, BM1, BM2, or the like. In some embodiments, the backside conductor is used instead of forming an electrical connection through the well region and the backside conductor is electrically isolated from the well region. In some embodiments, the well region and the backside conductor are electrically connected.

Table 1 below summarizes features of the ROM devices of the above described FIGS. 2A through 14D, as well as additional devices (rows 14-24) corresponding to FIGS. 3A through 13C but implemented with backside metal connections. Row 14 (FIGS. 14A˜14D) corresponds to the device of row 1 (FIGS. 2A˜2C) implemented with the backside metal connection. Rows 14-24 respectively correspond to the devices of rows 2˜12 implemented with the backside metal connection.

TABLE 1

| | | Cell Type | | | |
|---|---|---|---|---|---|
| | | (2T, 1.5T | Code on | M0 track | |
| | | CNOD, 1.5T | (Code on BL, | (BL = VSS, | Metal |
| Row | Figure | CPODE) | Code on VSS) | BL ≠ VSS) | (M0, BM0) |
| 1 | 2A~2C | 2T | BL | BL = VSS | M0 |
| 2 | 3A~3C | 2T | BL | BL ≠ VSS | M0 |
| 3 | 4A~4C | 2T | VSS | BL = VSS | M0 |
| 4 | 5A~5C | 2T | VSS | BL ≠ VSS | M0 |
| 5 | 6A~6C | 1.5T CNOD | BL | BL = VSS | M0 |
| 6 | 7A~7C | 1.5T CNOD | BL | BL ≠ VSS | M0 |
| 7 | 8A~8C | 1.5T CNOD | VSS | BL = VSS | M0 |
| 8 | 9A~9C | 1.5T CNOD | VSS | BL ≠ VSS | M0 |
| 9 | 10A~10C | 1.5T CPODE | BL | BL = VSS | M0 |
| 10 | 11A~11C | 1.5T CPODE | BL | BL ≠ VSS | M0 |
| 11 | 12A~12C | 1.5T CPODE | VSS | BL = VSS | M0 |
| 12 | 13A~13C | 1.5T CPODE | VSS | BL ≠ VSS | M0 |
| 13 | 14A~14D | 2T | BL | BL = VSS | BM0 |
| 14 | — | 2T | BL | BL ≠ VSS | BM0 |
| 15 | — | 2T | VSS | BL = VSS | BM0 |
| 16 | — | 2T | VSS | BL ≠ VSS | BM0 |
| 17 | — | 1.5T CNOD | BL | BL = VSS | BM0 |
| 18 | — | 1.5T CNOD | BL | BL ≠ VSS | BM0 |
| 19 | — | 1.5T CNOD | VSS | BL = VSS | BM0 |
| 20 | — | 1.5T CNOD | VSS | BL ≠ VSS | BM0 |
| 21 | — | 1.5T CPODE | BL | BL = VSS | BM0 |
| 22 | — | 1.5T CPODE | BL | BL ≠ VSS | BM0 |
| 23 | — | 1.5T CPODE | VSS | BL = VSS | BM0 |
| 24 | — | 1.5T CPODE | VSS | BL ≠ VSS | BM0 |

In some embodiments, one or more cell types are used in a same semiconductor device. In at least one embodiment, a ROM bitcell array uses a mixture of cell types, e.g., 2T, 1.5T CNOD, and/or 1.5T CPODE. In some embodiments, one transistor or more than two transistors are used for bitcells. In various embodiments, bitcell transistors have one or more gate structures. Further, in various embodiments, some routing, e.g., for bitline, wordline, and/or reference signals and/or voltages, is moved from a frontside metal layer such as M0 to one or more of a well region or a backside conductor. Additionally, in various embodiments, the ROM bitcells are implemented in NMOS or PMOS. In some embodiments, a ROM semiconductor device is implemented with one or more of a gate all-around bitcell transistor, a forksheet structure transistor, a CFET, using a mesa well architecture, or the like.

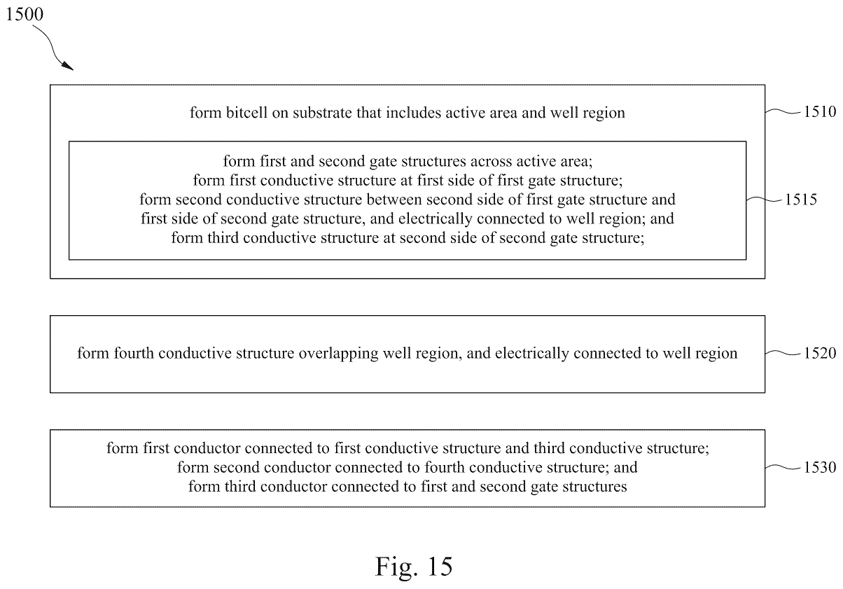

FIG. 15 is a flowchart of a method 1500 of fabricating a semiconductor device according to at least one embodiment.

The method 1500 includes an operation 1510 of forming a bitcell on a substrate that includes and active area and a well region. The forming the bitcell includes a suboperation 1515 of forming first and second gate structures across the active area; forming a first conductive structure at a first side of the first gate structure; forming a second conductive structure between a second side of the first gate structure and a first side of the second gate structure, and electrically connected to the well region; and forming a third conductive structure at a second side of the second gate structure.

The method 1500 also includes an operation 1520 of forming a fourth conductive structure overlapping the well region, and electrically connected to the well region.

The method 1500 also includes an operation 1530 of forming a first conductor connected to the first conductive structure and the third conductive structure; forming a second conductor connected to the fourth conductive structure; and forming a third conductor connected to the first and second gate structures.

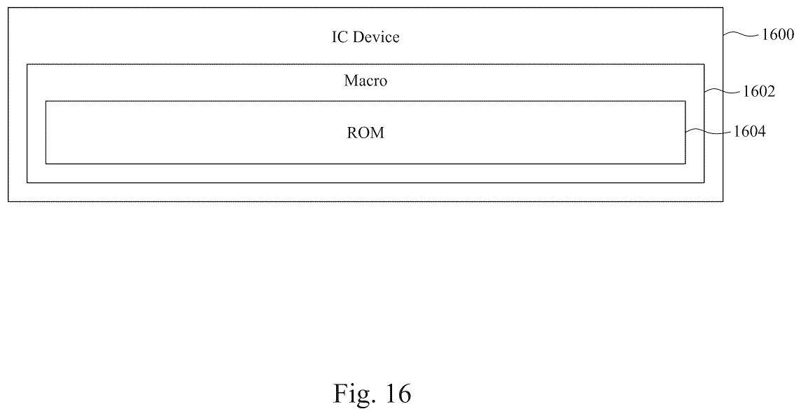

FIG. 16 is a block diagram of an IC device, according to at least one embodiment.

In FIG. 16, an IC device 1600 includes a macro 1602. In some embodiments, the macro 1602 includes one or more of a memory, a power grid, a cell or cells, an inverter, a latch, a buffer and/or any other type of circuit arrangement that may be represented digitally in a cell library. In some embodiments, the macro 1602 is understood in the context of an analogy to the architectural hierarchy of modular programming, in which subroutines/procedures are called by a main program (or by other subroutines) to carry out a given computational function. In this context, the IC device 1600 uses the macro 1602 to perform one or more given functions. Accordingly, in this context and in terms of architectural hierarchy, the IC device 1600 is analogous to the main program and the macro 1602 is analogous to subroutines/procedures. In some embodiments, the macro 1602 is a soft macro. In some embodiments, the macro 1602 is a hard macro. In some embodiments, the macro 1602 is a soft macro that is described digitally in register-transfer level (RTL) code. In some embodiments, synthesis, placement, and routing have yet to have been performed on the macro 1602 such that the soft macro can be synthesized, placed, and routed for a variety of process nodes. In some embodiments, the macro 1602 is a hard macro that is described digitally in a binary file format (e.g., Graphic Database System II (GDSII) stream format), where the binary file format represents planar geometric shapes, text labels, other information, and the like of one or more layouts of the macro 1602 in hierarchical form. In some embodiments, synthesis, placement, and routing have been performed on the macro 1602 such that the hard macro is specific to a particular process node. In FIG. 16, the macro 1602 includes a region 1604 that includes a ROM, e.g., corresponding one or more of the ROM semiconductor devices described above and/or represented in Table 1.

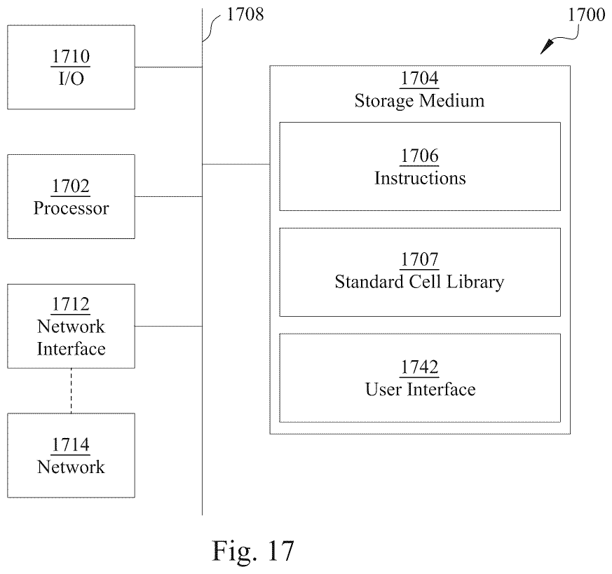

FIG. 17 is a block diagram of an electronic design automation (EDA) system 1700 in accordance with some embodiments.

In some embodiments, EDA system 1700 includes an Automatic Place & Route (APR) system. Methods of designing layouts representing wire routing arrangements of semiconductor devices in accordance with one or more embodiments are implementable, for example, using EDA system 1700, according to at least one embodiment.

In some embodiments, EDA system 1700 is a general-purpose computing device including a hardware processor 1702 and a non-transitory, computer-readable storage medium 1704. The computer-readable storage medium 1704, amongst other things, is encoded with, i.e., stores, computer program code 1706, i.e., a set of executable instructions. Execution of instructions 1706 by the processor 1702 represents (at least in part) an EDA tool that implements a portion or all of processes and/or methods for, e.g., synthesis, placement, and routing of a region that includes a ROM, e.g., corresponding one or more of the ROM semiconductor devices described above and/or represented in Table 1, in accordance with one or more embodiments (hereinafter, the noted processes and/or methods).

The processor 1702 is electrically coupled to the computer-readable storage medium 1704 via a bus 1708. The processor 1702 is also electrically coupled to an I/O interface 1710 by the bus 1708. A network interface 1712 is also electrically connected to processor 1702 via the bus 1708. Network interface 1712 is connected to a network 1714, so that the processor 1702 and the computer-readable storage medium 1704 are capable of connecting to external elements via network 1714. Processor 1702 is configured to execute computer program code 1706 encoded in the computer-readable storage medium 1704 in order to cause EDA system 1700 to be usable for performing a portion or all of the noted processes and/or methods. In one or more embodiments, processor 1702 is a central processing unit (CPU), a multi-processor, a distributed processing system, an application specific integrated circuit (ASIC), and/or a suitable processing unit.

In one or more embodiments, the computer-readable storage medium 1704 is an electronic, magnetic, optical, electromagnetic, infrared, and/or a semiconductor system (or apparatus or device). Examples of the computer-readable storage medium 1704 include a semiconductor or solid-state memory, a magnetic tape, a removable computer diskette, a random access memory (RAM), a read-only memory (ROM), a rigid magnetic disk, and/or an optical disk. In one or more embodiments using optical disks, the computer-readable storage medium 1704 includes a compact disk read-only memory (CD-ROM), a compact disk-read/write (CD-R/W), and/or a digital video disc (DVD).

In one or more embodiments, the computer-readable storage medium 1704 stores computer program code 1706 configured to cause EDA system 1700 (where such execution represents (at least in part) the EDA tool) to be usable for performing a portion or all of the noted processes and/or methods. In one or more embodiments, the computer-readable storage medium 1704 also stores information that facilitates performing a portion or all of the noted processes and/or methods. In one or more embodiments, the computer-readable storage medium 1704 stores library 1707 of standard cells including such standard cells as disclosed herein.

The EDA system 1700 includes I/O interface 1710. I/O interface 1710 is coupled to external circuitry. In one or more embodiments, I/O interface 1710 includes a keyboard, keypad, mouse, trackball, trackpad, touchscreen, and/or cursor direction keys for communicating information and commands to processor 1702.

The EDA system 1700 also includes network interface 1712 coupled to processor 1702. Network interface 1712 allows EDA system 1700 to communicate with network 1714, to which one or more other computer systems are connected. Network interface 1712 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more EDA systems 1700.

The EDA system 1700 is configured to receive information through I/O interface 1710. The information received through I/O interface 1710 includes one or more of instructions, data, design rules, libraries of standard cells, and/or other parameters for processing by processor 1702. The information is transferred to processor 1702 via the bus 1708. EDA system 1700 is configured to receive information related to a user interface (UI) through I/O interface 1710. The information is stored in the computer-readable storage medium 1704 as user interface (UI) 1742.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 1700. In some embodiments, a layout that includes standard cells is generated using a tool such as VIRTUOSO® available from Cadence Design Systems, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

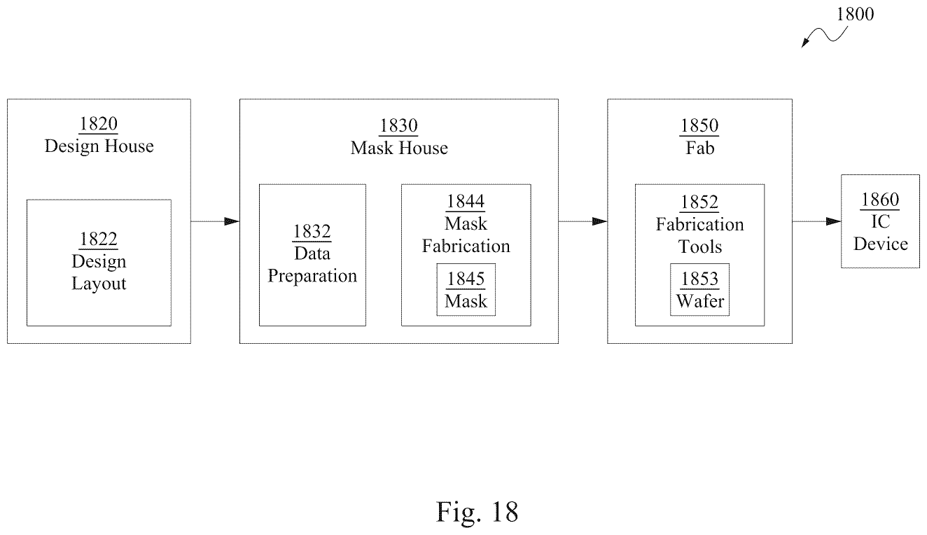

FIG. 18 is a block diagram of an integrated circuit (IC) manufacturing system 1800, and an IC manufacturing flow associated therewith, according to at least one embodiment.

In some embodiments, based on a layout, at least one of (A) one or more semiconductor masks or (B) at least one component in a layer of a semiconductor integrated circuit is fabricated using the IC manufacturing system 1800.

In FIG. 18, the IC manufacturing system 1800 includes entities, such as a design house 1820, a mask house 1830, and an IC manufacturer/fabricator (fab) 1850, that interact with one another in the design, development, and manufacturing cycles and/or services related to manufacturing an IC device 1860, e.g., corresponding to the ROM devices described above with reference to Table 1. The entities in the IC manufacturing system 1800 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of the design house 1820, the mask house 1830, and the IC fab 1850 are owned by a single larger company. In some embodiments, two or more of the design house 1820, the mask house 1830, and the IC fab 1850 coexist in a common facility and use common resources.

The design house (or design team) 1820 generates an IC design layout 1822. The IC design layout 1822 includes various geometrical patterns designed for an IC device 1860. The geometrical patterns correspond to patterns of metal, oxide, or semiconductor layers that make up the various components of the IC device 1860 to be fabricated. The various layers combine to form various IC features. For example, a portion of the IC design layout 1822 includes various IC features, such as an active region, gate electrode, source and drain, metal lines or vias of an interlayer interconnect, UTM interconnect structure, or the like, passivation layer structures, openings for bonding pads, and conductive bumps to be formed in a semiconductor substrate (such as a silicon wafer) and various material layers disposed on the semiconductor substrate. The design house 1820 implements a formal design procedure to form the IC design layout 1822. The design procedure includes one or more of logic design, physical design or place-and-route operation. The IC design layout 1822 is presented in one or more data files having information of the geometrical patterns. For example, the IC design layout 1822 can be expressed in a GDSII file format or DFII file format.

The mask house 1830 includes mask data preparation 1832 and mask fabrication 1844. The mask house 1830 uses the IC design layout 1822 to manufacture one or more masks 1845 to be used for fabricating the various layers of the IC device 1860 according to the IC design layout 1822. The mask house 1830 performs the mask data preparation 1832, where the IC design layout 1822 is translated into a representative data file (RDF). The mask data preparation 1832 provides the RDF to the mask fabrication 1844. The mask fabrication 1844 includes a mask writer. The mask writer converts the RDF to an image on a substrate, such as a mask (reticle) 1845 or a semiconductor wafer 1853. The IC design layout 1822 is manipulated by the mask data preparation 1832 to comply with particular characteristics of the mask writer and/or requirements of the IC fab 1850. In FIG. 18, the mask data preparation 1832 and the mask fabrication 1844 are illustrated as separate elements. In some embodiments, the mask data preparation 1832 and the mask fabrication 1844 can be collectively referred to as mask data preparation.

In some embodiments, the mask data preparation 1832 includes optical proximity correction (OPC) that uses lithography enhancement techniques to compensate for image errors, such as those that can arise from diffraction, interference, other process effects and the like. The OPC adjusts the IC design layout 1822. In some embodiments, the mask data preparation 1832 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 1832 includes a mask rule checker (MRC) that checks the IC design layout 1822 that has undergone processes in the OPC with a set of mask creation rules containing geometric and/or connectivity restrictions to ensure sufficient margins, to account for variability in semiconductor manufacturing processes, and the like. In some embodiments, the MRC modifies the IC design layout 1822 to compensate for limitations during the mask fabrication 1844, which may undo part of the modifications performed by OPC in order to meet mask creation rules.

In some embodiments, the mask data preparation 1832 includes lithography process checking (LPC) that simulates processing that will be implemented by the IC fab 1850 to fabricate the IC device 1860. The LPC simulates this processing based on the IC design layout 1822 to create a simulated manufactured device, such as the IC device 1860. The processing parameters in LPC simulation can include parameters associated with various processes of the IC manufacturing cycle, parameters associated with tools used for manufacturing the IC, and/or other aspects of the manufacturing process. The LPC takes into account various factors, such as aerial image contrast, depth of focus (DOF), mask error enhancement factor (MEEF), other suitable factors, and the like or combinations thereof. In some embodiments, after a simulated manufactured device has been created by LPC, if the simulated device is not close enough in shape to satisfy design rules, OPC and/or MRC are repeated to further refine the IC design layout 1822.

It should be understood that the above description of the mask data preparation 1832 has been simplified for the purposes of clarity. In some embodiments, the mask data preparation 1832 includes additional features such as a logic operation (LOP) to modify the IC design layout 1822 according to manufacturing rules. Additionally, the processes applied to the IC design layout 1822 during the mask data preparation 1832 may be executed in a variety of different orders.

After the mask data preparation 1832 and during the mask fabrication 1844, a mask 1845 or a group of masks 1845 are fabricated based on the modified IC design layout 1822. In some embodiments, the mask fabrication 1844 includes performing one or more lithographic exposures based on the IC design layout 1822. In some embodiments, an electron-beam (e-beam) or a mechanism of multiple e-beams is used to form a pattern on a mask (photomask or reticle) 1845 based on the modified IC design layout 1822. The mask 1845 can be formed in various technologies. In some embodiments, the mask 1845 is formed using binary technology. In some embodiments, a mask pattern includes opaque regions and transparent regions. A radiation beam, such as an ultraviolet (UV) beam, used to expose the image sensitive material layer (e.g., photoresist) that has been coated on a wafer, is blocked by the opaque region and transmits through the transparent regions. In one example, a binary mask version of the mask 1845 includes a transparent substrate (e.g., fused quartz) and an opaque material (e.g., chromium) coated in the opaque regions of the binary mask. In another example, the mask 1845 is formed using a phase shift technology. In a phase shift mask (PSM) version of the mask 1845, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 1844 is used in a variety of processes. For example, such a mask(s) is used in an ion implantation process to form various doped regions in a semiconductor wafer 1853, in an etching process to form various etching regions in the semiconductor wafer 1853, and/or in other suitable processes.

The IC fab 1850 is an IC fabrication business that includes one or more manufacturing facilities for the fabrication of a variety of different IC products. In some embodiments, the IC fab 1850 is a semiconductor foundry. For example, there may be a manufacturing facility for the front end fabrication of a plurality of IC products (front-end-of-line (FEOL) fabrication), while a second manufacturing facility may provide the back end fabrication for the interconnect and packaging of the IC products (back-end-of-line (BEOL) fabrication), and a third manufacturing facility may provide other services for the foundry business.

The IC fab 1850 includes fabrication tools 1852 configured to execute various manufacturing operations on semiconductor wafer 1853 such that the IC device 1860 is fabricated in accordance with the mask(s), e.g., the mask 1845. In various embodiments, the fabrication tools 1852 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

The IC fab 1850 uses the mask(s) 1845 fabricated by the mask house 1830 to fabricate the IC device 1860. Thus, the IC fab 1850 at least indirectly uses the IC design layout 1822 to fabricate the IC device 1860. In some embodiments, the semiconductor wafer 1853 is fabricated by the IC fab 1850 using the mask(s) 1845 to form the IC device 1860. In some embodiments, the IC fabrication includes performing one or more lithographic exposures based at least indirectly on the IC design layout 1822. The semiconductor wafer 1853 includes a silicon substrate or other proper substrate having material layers formed thereon. The semiconductor wafer 1853 further includes one or more of various doped regions, dielectric features, multilevel interconnects, and the like (formed at subsequent manufacturing steps).

Details regarding an integrated circuit (IC) manufacturing system (e.g., the IC manufacturing system 1800 of FIG. 18), and an IC manufacturing flow associated therewith are found, e.g., in U.S. Pat. No. 9,256,709, granted Feb. 9, 2016, U.S. Pre-Grant Publication No. 2015/0278429, published Oct. 1, 2015, U.S. Pre-Grant Publication No. 2014/0040838, published Feb. 6, 2014, and U.S. Pat. No. 7,260,442, granted Aug. 21, 2007, the entireties of each of which are hereby incorporated by reference.

In some embodiments, a semiconductor device include a substrate including an active area and a well region under the active area; a bitcell vertically overlapping the well region, the bitcell including: a first gate structure and a second gate structure extending in a first direction across the active area and spaced apart in a second direction; a first conductive structure at a first side of the first gate structure; a second conductive structure between a second side of the first gate structure and a first side of the second gate structure; and a third conductive structure at a second side of the second gate structure; a fourth conductive structure vertically overlapping the well region; a first conductor connected to the first conductive structure and the third conductive structure; a second conductor connected to the fourth conductive structure; and a third conductor connected to the first and second gate structures. The second and fourth conductive structures are electrically connected to the well region.

In some embodiments, a semiconductor device includes a substrate including an active area and a well region under the active area; a first gate structure, a second gate structure, a third gate structure, and a fourth gate structure extending in a first direction across the active area, and spaced apart in a second direction; a first conductive structure at a first side of the first gate structure; a second conductive structure between a second side of the first gate structure and a first side of the second gate structure; a third conductive structure between a second side of the second gate structure and a first side of the third gate structure; a fourth conductive structure between a second side of the third gate structure and a first side of the fourth gate structure; a fifth conductive structure at a second side of the fourth gate structure; a sixth conductive structure vertically overlapping the well region; a first conductor connected to the first, third, and fifth conductive structures; a second conductor connected to the sixth conductive structure; a third conductor connected to the third and fourth gate structures; and a fourth conductor connected to the first and second gate structures. The fourth and sixth conductive structures are electrically connected to the well region.

In some embodiments, a method of fabricating a semiconductor device includes forming a bitcell on a substrate that includes an active area and a well region under the active area, wherein the bitcell is formed to vertically overlap the well region, and the forming a bitcell includes: forming a first gate structure and a second gate structure extending in a first direction across the active area and spaced apart in a second direction; forming a first conductive structure at a first side of the first gate structure; forming a second conductive structure between a second side of the first gate structure and a first side of the second gate structure; and forming a third conductive structure at a second side of the second gate structure; forming a fourth conductive structure vertically overlapping the well region; forming a first conductor connected to the first conductive structure and the third conductive structure; forming a second conductor connected to the fourth conductive structure; and forming a third conductor connected to the first and second gate structures. The second and fourth conductive structures are formed to be electrically connected to the well region.

It will be appreciated that features, characteristics, and/or elements described in connection with a particular embodiment are usable singly or in combination with features, characteristics, and/or elements described in connection with one or more other embodiments unless otherwise specifically indicated.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device comprising:
a substrate including an active area and a well region under the active area;
a bitcell vertically overlapping the well region, the bitcell including:
a first gate structure and a second gate structure extending in a first direction across the active area and spaced apart in a second direction;
a first conductive structure at a first side of the first gate structure;
a second conductive structure between a second side of the first gate structure and a first side of the second gate structure; and
a third conductive structure at a second side of the second gate structure;
a fourth conductive structure vertically overlapping the well region;
a first conductor connected to the first conductive structure and the third conductive structure;
a second conductor connected to the fourth conductive structure; and
a third conductor connected to the first and second gate structures,
wherein:
the second and fourth conductive structures are electrically connected to the well region.

2. The semiconductor device of claim 1, further comprising:
a first epitaxial structure under the second conductive structure and in contact with the well region; and
a second epitaxial structure under the fourth conductive structure and in contact with the well region.

3. The semiconductor device of claim 2, wherein:
the well region conducts a first reference voltage between the second and fourth conductive structures, and
the bitcell encodes a first logic value.

4. The semiconductor device of claim 2, further comprising:
an insulating structure on the well region,
wherein:
the first and second epitaxial structures extend through openings in the insulating structure to contact the well region.

5. The semiconductor device of claim 1, wherein:
the first conductor is configured as a bitline,
the second conductor is configured to provide a first reference voltage, and
the third conductor is configured as a wordline.

6. The semiconductor device of claim 1, wherein:
first conductor is configured to provide a first reference voltage,
the second conductor is configured as a bitline, and
the third conductor is configured as a wordline.

7. A semiconductor device comprising:
a substrate including an active area and a well region under the active area;
a first gate structure, a second gate structure, a third gate structure, and a fourth gate structure extending in a first direction across the active area, and spaced apart in a second direction;
a first conductive structure at a first side of the first gate structure;
a second conductive structure between a second side of the first gate structure and a first side of the second gate structure;
a third conductive structure between a second side of the second gate structure and a first side of the third gate structure;
a fourth conductive structure between a second side of the third gate structure and a first side of the fourth gate structure;
a fifth conductive structure at a second side of the fourth gate structure;
a sixth conductive structure vertically overlapping the well region;
a first conductor connected to the first, third, and fifth conductive structures;
a second conductor connected to the sixth conductive structure;
a third conductor connected to the third and fourth gate structures; and
a fourth conductor connected to the first and second gate structures,
wherein:
the fourth and sixth conductive structures are electrically connected to the well region.

8. The semiconductor device of claim 7, wherein:
the first, second, third, and fifth conductive structures are free of a direct electrical connection to the well region.

9. The semiconductor device of claim 8, further comprising:
an insulating structure below the first, second, third, and fifth conductive structures from the well region,
wherein the insulating structure has openings therein below the fourth and sixth conductive structure.

10. The semiconductor device of claim 7, further comprising:
a first epitaxial structure under the fourth conductive structure and in contact with the well region; and
a second epitaxial structure under the sixth conductive structure and in contact with the well region.

11. The semiconductor device of claim 10, further comprising:
an insulating structure on the well region,
wherein:
the first and second epitaxial structures extend through openings in the insulating structure to contact the well region.

12. The semiconductor device of claim 7, wherein:
the first conductor is configured as a bitline,
the second conductor is configured to provide a first reference voltage, and
the third and fourth conductors are configured as wordlines.

13. The semiconductor device of claim 7, wherein:
the first conductor is configured to provide a first reference voltage,
the second conductor is configured as a bitline, and
the third and fourth conductors are configured as wordlines.

14. The semiconductor device of claim 7, wherein:
the well region conducts a first reference voltage between the fourth and sixth conductive structures,
a bitcell corresponding to the first conductor is configured to store a first logic value, and
a bitcell corresponding to the second conductor is configured to store a second logic value different from the first logic value.

15. A method of fabricating a semiconductor device, comprising:
forming a bitcell on a substrate that includes an active area and a well region under the active area, wherein:
the bitcell is formed to vertically overlap the well region, and
the forming a bitcell includes:
forming a first gate structure and a second gate structure extending in a first direction across the active area and spaced apart in a second direction;
forming a first conductive structure at a first side of the first gate structure;
forming a second conductive structure between a second side of the first gate structure and a first side of the second gate structure; and
forming a third conductive structure at a second side of the second gate structure;
forming a fourth conductive structure vertically overlapping the well region;
forming a first conductor connected to the first conductive structure and the third conductive structure;
forming a second conductor connected to the fourth conductive structure; and
forming a third conductor connected to the first and second gate structures,
wherein:
the second and fourth conductive structures are formed to be electrically connected to the well region.

16. The method of claim 15, further comprising:
forming a first epitaxial structure in contact with the well region, the second conductive structure being over the first epitaxial structure; and
forming a second epitaxial structure in contact with the well region, the second epitaxial structure being under the fourth conductive structure.

17. The method of claim 16, wherein:
the second and fourth conductive structures are formed to be electrically connected by the well region, and
the bitcell is formed to encode a first logic value.

18. The method of claim 16, further comprising:
forming an insulating structure on the well region; and
forming first and second openings in the insulating structure,
wherein:
the first and second epitaxial structures are formed in the first and second openings, and contact the well region.

19. The method of claim 15, further comprising:
forming a third gate structure and a fourth gate structure;
forming a fifth conductive structure at a first side of the third gate structure;
forming a sixth conductive structure between a second side of the third gate structure and a first side of the fourth gate structure; and
forming a seventh conductive structure between a second side of the fourth gate structure and the first side of the first gate structure.

20. The method of claim 19, wherein:
the fourth conductive structure is formed to be electrically disconnected from the well region, and is included in another bitcell that encodes a second logic value.
